(19) United States
(12) Patent Application Publication
(10) Pub. No.: US 2026/0231652 A1
(43) Pub. Date: Aug. 6, 2026

(54) DISPLAY PANEL, METHOD OF MANUFACTURING THE DISPLAY PANEL, ELECTRONIC DEVICE, AND METHOD OF MANUFACTURING THE ELECTRONIC DEVICE

(71) Applicant: Samsung Display Co., Ltd., Yongin-si (KR)

(72) Inventors: Seongsik Ahn, Yongin-si (KR); Namjin Kim, Yongin-si (KR); Jinho Kim, Yongin-si (KR); Jinyoung Ro, Yongin-si (KR); Taekyu Shim, Yongin-si (KR); Taewoo Lim, Yongin-si (KR); Taekyoung Hwang, Yongin-si (KR)

(21) Appl. No.: 19/455,302

(22) Filed: Jan. 21, 2026

(30) Foreign Application Priority Data
Feb. 5, 2025 (KR) 10-2025-0014712

(51) Int. Cl. H10K 59/80; H10K 59/12; G09G 3/3233

(52) U.S. Cl. CPC H10K 59/873; H10K 59/1201; G09G 3/3233; G09G 2300/0426; G09G 2300/0842; G09G 2354/00

(57) ABSTRACT

According to an aspect, provided is a display panel including a substrate including an opening area, a middle area at least partially surrounding the opening area in plan view, and a display area at least partially surrounding the middle area in plan view, a light-emitting diode in the display area, a first dam in the middle area, and including two or more selected from a first organic part, a first inorganic part, or a first metal part, and a second dam between the first dam and the display area, and including a second organic part, and a second metal part in the second organic part and having a part protruding beyond a side of the second organic part in plan view.

### CROSS-REFERENCE TO RELATED APPLICATION

The present application claims priority to, and the benefit of, Korean Patent Application No. 10-2025-0014712, filed on February 5, 2025, in the Korean Intellectual Property Office, the entire disclosure of which is incorporated herein by reference.

### BACKGROUND

### 1. Field

One or more embodiments relate to a display panel and a method of manufacturing the display panel, to an electronic device including the display panel, and to a method of manufacturing the electronic device.

### 2. Description of the Related Art

An electronic device may display a video and/or an image by using an arranged display panel. Recently, the usage of the display panel varies, and various functions are proposed to be integrated with or connected to the display panel. Various schemes are proposed to ensure basic functions of the display panel for representing an image and simultaneously to add various functions.

The electronic device may include, as well as the display panel, a component for performing other functions. For example, the electronic device may include the component including a camera, a sensor, etc. The component may be provided at a rear surface of the display panel. To facilitate the component to smoothly perform its function, an opening may be defined in an area of the display panel that overlaps the component. The opening may be defined while penetrating through the display panel. The opening of the display panel may be implemented in a manner that a plurality of layers are formed on a substrate, the plurality of layers and the substrate are cut, and then a part corresponding to the opening is removed.

### SUMMARY

In a process of cutting a substrate and a plurality of layers on the substrate along a cutting line so as to form an opening of a display panel, and removing a part corresponding to the opening, delamination between some of the plurality of layers on the substrate may occur. One or more embodiments include a structure for reducing or preventing the delamination.

Additional aspects will be set forth in part in the description that follows and, in part, will be apparent from the description, or may be learned by practice of the presented embodiments of the disclosure.

According to one or more embodiments, a display panel includes a substrate including an opening area, a middle area at least partially surrounding the opening area in plan view, and a display area at least partially surrounding the middle area in plan view, a light-emitting diode in the display area, a first dam in the middle area, and including two or more selected from a first organic part, a first inorganic part, or a first metal part, and a second dam between the first dam and the display area, and including a second organic part, and a second metal part in the second organic part and having a part protruding beyond a side of the second organic part.

The first dam may include the first inorganic part above the substrate, a first-1 organic part covering the first inorganic part, and a first-2 organic part covering the first-1 organic part.

The first dam may include the first inorganic part above the substrate, a first-1 metal part in the first inorganic part, a first-2 metal part above the first inorganic part, and a first-3 metal part above the first-2 metal part.

The display panel may further include an encapsulation layer covering the first dam and the second dam, and directly contacting the first-2 metal part and the first-3 metal part of the first dam.

The first dam may further include a first-1 organic part covering the first inorganic part, the first-1 metal part, the first-2 metal part, and the first-3 metal part.

The first dam may further include a first-3 organic part between the first-2 metal part and the first-3 metal part, and covering the first inorganic part, the first-1 metal part, the first-2 metal part.

The first-3 metal part of the first dam may be at a same layer as the second metal part of the second dam.

The substrate may define an opening corresponding to the opening area.

The light-emitting diode may include a first electrode above the substrate, an emission layer above the first electrode, and a second electrode above the emission layer and disconnected at an edge of the second metal part that extends toward the middle area and protrudes over the side of the second organic part of the second dam.

According to one or more embodiments, a method of manufacturing a display panel may include forming a light-emitting diode in a display area of a substrate including an opening area, a middle area at least partially surrounding the opening area in plan view, and the display area at least partially surrounding the middle area in plan view, forming a first dam extending over the opening area and the middle area, forming, between the first dam and the display area, a second dam including a second organic part, and a second metal part in the second organic part, and having a part protruding over a side of the second organic part, and cutting the first dam and the substrate along a boundary between the opening area and the middle area.

The first dam may include a first inorganic part above the substrate, a first-1 organic part above the first inorganic part, and a first-2 organic part above the first-1 organic part.

A width of the first dam may be greater than a distance between the first dam and the second dam.

A height of the first dam may be equal to or greater than a height of the second dam.

The first dam may further include a first-3 organic part between the first inorganic part and the first-1 organic part.

The method may further include arranging, in the opening area, an inner dam having a same stack structure as the first dam.

The method may further include arranging two neighboring inner dams having a distance therebetween that is less than a width of the inner dams.

The method may further include arranging an encapsulation layer covering the first dam and the second dam, wherein the encapsulation layer is also cut in the cutting of the first dam and the substrate.

The method may further include removing a part of the substrate and a part of the first dam corresponding to the opening area.

The method may further include manufacturing an electronic device, by manufacturing the display panel, and coupling the display panel with a housing.

According to one or more embodiments, an electronic device includes a display panel, wherein the display panel includes a substrate including an opening area, a middle area at least partially surrounding the opening area in plan view, and a display area at least partially surrounding the middle area in plan view, a light-emitting diode in the display area, a first dam in the middle area, and including two or more selected from a first organic part, a first inorganic part, or a first metal part, and a second dam between the first dam and the display area, and including a second organic part, and a second metal part in the second organic part, and having a part protruding over a side of the second organic part.

### BRIEF DESCRIPTION OF THE DRAWINGS

The above and other aspects of embodiments of the disclosure will be more apparent from the following description taken in conjunction with the accompanying drawings, in which:

FIG. 1 is a block diagram of an electronic device according to one or more embodiments;

FIGS. 2, 3,and 4 are schematic diagrams of an electronic device according to various embodiments;

FIG. 5 is a perspective view schematically illustrating an electronic device according to one or more embodiments;

FIG. 6 is a cross-sectional view of an electronic device according to one or more embodiments;

FIG. 7 is a circuit diagram schematically illustrating a light-emitting diode and a pixel circuit connected to the light-emitting diode, which are included in a pixel of a display panel, according to one or more embodiments;

FIG. 8 is a cross-sectional view of a display area of a display panel according to one or more embodiments;

FIGS. 9A and 9B are cross-sectional views of a display panel according to one or more embodiments;

FIGS. 10A and 10B are cross-sectional views of a display panel according to one or more embodiments;

FIGS. 11A and 11B are cross-sectional views of a display panel according to one or more embodiments;

FIGS. 12A and 12B are cross-sectional views of a display panel according to one or more embodiments;

FIGS. 13A and 13B are cross-sectional views of a display panel according to one or more embodiments;

FIGS. 14A and 14B are cross-sectional views of a display panel according to one or more embodiments;

FIGS. 15A and 15B are cross-sectional views of a display panel according to one or more embodiments;

FIGS. 16A and 16B are cross-sectional views of a display panel according to one or more embodiments; and

FIGS. 17A and 17B are cross-sectional views of a display panel according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions, such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions, such as “at least one of,” “a plurality of,” “one of,” and other prepositional phrases, when preceding a list of elements, modify the entire list of elements and do not modify the individual elements of the list. When "C to D" is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer, or section described below could be termed a second element, component, region, layer, or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/- 5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, 5% of the stated value. Further, the use of “may” when describing embodiments of the present disclosure refers to “one or more embodiments of the present disclosure.” Furthermore, the expression “being the same” may mean “being substantially the same.” In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

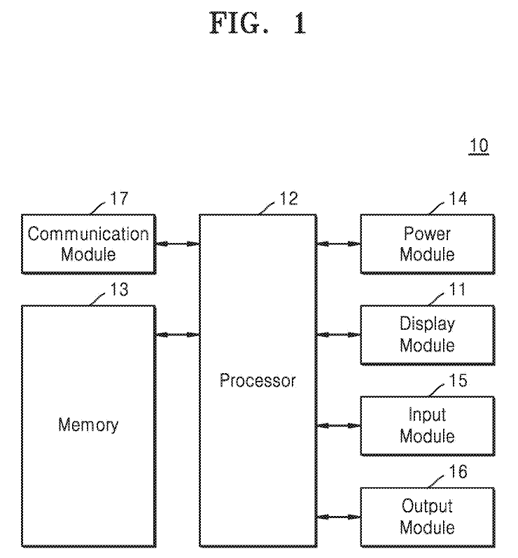

FIG. 1 is a block diagram of an electronic device 10 according to one or more embodiments. Referring to FIG. 1, the electronic device 10 may include a display panel 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller. In one or more embodiments, the processor 12 may be provided by being functionally or structurally divided into at least two processors. For example, the processor 12 may include a main processor in the form of a first driving chip including a CPU, and an auxiliary processor in the form of a second driving chip including a controller configured to receive an image signal from the main processor and process the image signal to be adapted to an interface specification of the display panel 11.

The memory 13 may include at least one of a non-volatile memory or a volatile memory. The memory 13 may store data information required for an operation of the processor 12 or the display panel 11. When the processor 12 executes an application stored in the memory 13, an image data signal and/or an input control signal may be transmitted to the display panel 11, and the display panel 11 may process the provided signal, and thus, may output image information via a display screen.

The power module 14 may include a power supply module, such as a power adaptor or a battery device, and a power conversion module for generating, by converting power supplied by the power supply module, power required for an operation of the electronic device 10. Power conversion by the power conversion module may include, but is not limited to, direct current (DC)-DC conversion, alternating current (AC)-DC conversion, and DC-AC conversion.

The electronic device 10 may further include an input module 15, a non-image output module 16, and/or a communication module 17.

The input module 15 may provide input information to the processor 12 and/or the display panel 11. The input module 15 may include not only physical buttons, a keyboard, and a microphone but also include various sensor modules. An example of a sensor module may include not only a touch sensor, a pressure sensor, a distance sensor, a position sensor, a digitizer, a motion recognition sensor, a camera sensor, a light-receiving sensor, a photoelectric conversion sensor, and/or a temperature sensor, but also may include a biometric sensor including a blood pressure sensor, a blood glucose sensor, an electrocardiogram sensor, a heart rate sensor, etc.

The non-image output module 16 may provide a user with information by receiving the information other than an image transmitted from the processor 12. An example of the non-image output module 16 may include an audio module, a haptic module, a light-emitting module, etc., and may also include other functional module (e.g., a cooling module of a refrigerator) dedicated to an electronic device.

The communication module 17 is a module to handle information transmission and reception between the electronic device 10 and an external device, and may include a receiver and a transmitter. The communication module 17 may include various wireless communication modules including a mobile communication module, a wireless-fidelity (Wi‑Fi®) module, a Bluetooth® module (Wi‑Fi® being a registered trademark of the non-profit Wi-Fi Alliance, and Bluetooth® being a registered trademark of Bluetooth Sig, Inc., Kirkland, WA), etc., or various wired communication modules.

At least one of elements of the electronic device 10 may be included in a display apparatus according to aforementioned embodiments. Also, some of separate modules functionally included in one module may be included in the display apparatus, and others may be provided separately from the display apparatus. For example, the display apparatus may include the display panel 11, and the processor 12, the memory 13, and the power module 14 may be provided in the form of other devices in the electronic device 10, not in the display apparatus. As another example, the power module 14 may be arranged in the display apparatus, and may provide power to the processor 12 and the memory 13 arranged in the electronic device 10, not in the display apparatus, but the disclosure is not limited thereto.

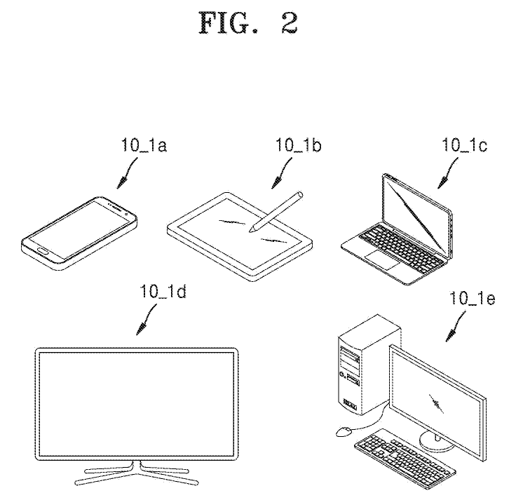

FIGS. 2 to 4 are schematic diagrams of an electronic device according to various embodiments. FIGS. 2 to 4 illustrate examples of various electronic devices to which display apparatuses according to embodiments are applied.

FIG. 2 illustrates a smartphone 10_1a, a tablet personal computer (PC) 10_1b, a laptop computer 10_1c, a television (TV) 10_1d, and a monitor for desk 10_1e.

The smartphone 10_1a may include an input module including a touch sensor, and a communication module, as well as a display panel. The smartphone 10_1a may process information received via the communication module or another input module, and thus, may display the information via a display panel of a display apparatus.

Similar to the smartphone 10_1a, each of the tablet PC 10_1b, the laptop computer 10_1c, the TV 10_1d, and the monitor for desk 10_1e may include a display panel and an input module, and, in some cases, may further include a communication module.

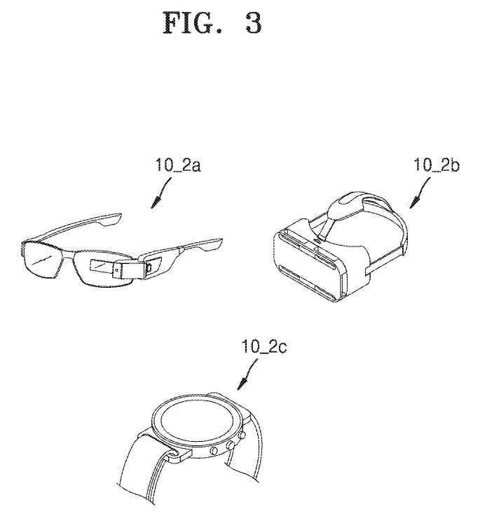

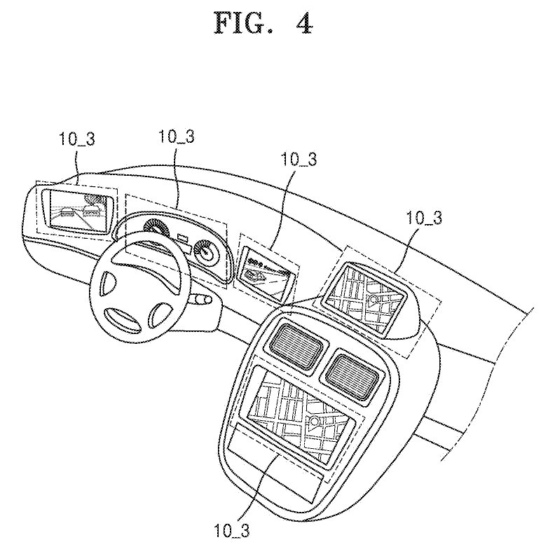

FIG. 3 illustrates an example in which an electronic device including a display panel is applied to a wearable electronic device. The wearable electronic device may include smart glasses 10_2a, a head-mounted display 10_2b, a smart watch 10_2c, or the like.

Each of the smart glasses 10_2a and the head-mounted display 10_2b may include a display panel for projecting a display image, and a reflector for reflecting a projected display screen and providing the reflected display screen to eyes of a user, and thus, may provide the user with a screen of a virtual reality or an augmented reality.

The smart watch 10_2c may include a biometric sensor as an input device, and may provide, via a display panel, a user with biometric information recognized via the biometric sensor.

FIG. 4 illustrates an example in which an electronic device 10_3 including a display panel is applied to a vehicle. For example, the electronic device 10_3 may be applied to a dashboard, a center console, etc. of the vehicle, or may be applied to a center information display (CID) arranged on the dashboard of the vehicle, a room mirror display replacing a side-view mirror of the vehicle, etc.

Although not illustrated, an electronic device to which a display apparatus according to embodiments is applied may include not only devices including an advertisement board, an electronic display board, a game player, etc. for mainly displaying a screen but also include various home appliances including a refrigerator, a washing machine, a dryer, an air conditioner, a robot cleaner, etc. for displaying information via a display panel. Also, when a display panel has a function for transmitting light, the display panel may be applied to a smart window, or an electronic device including a transparent display apparatus that displays both a background and a display image. Types of an electronic device according to embodiments are not limited to the examples, and application to other unstated various electronic devices may be possible.

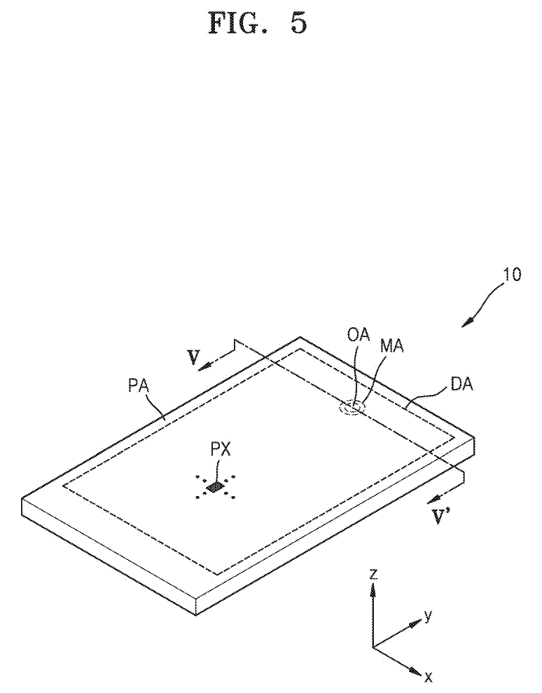

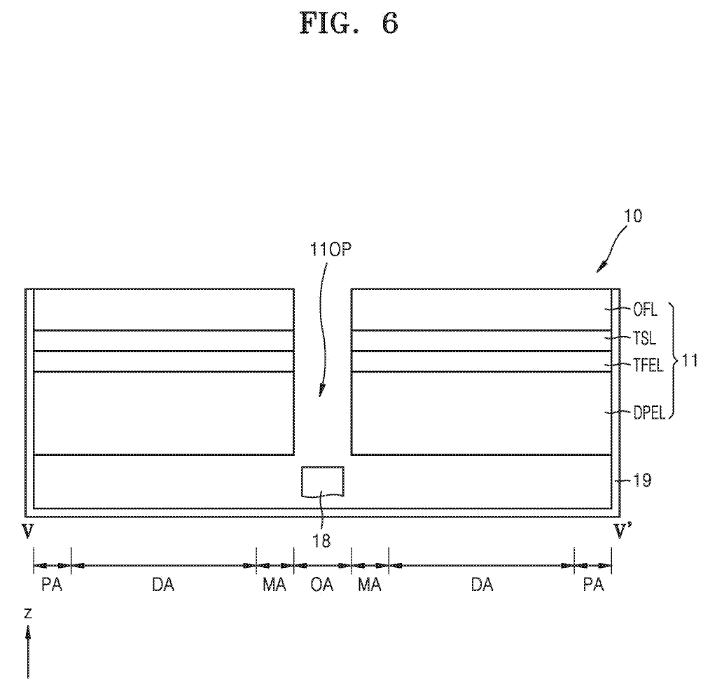

FIG. 5 is a perspective view schematically illustrating an electronic device according to one or more embodiments. FIG. 6 is a cross-sectional view of the electronic device according to one or more embodiments. FIG. 6 may correspond to the cross-sectional view of the electronic device, taken along the line V-V' of FIG. 5. FIGS. 5 and 6 illustrate one or more embodiments in which the electronic device 10 is a smartphone, but the disclosure is not limited thereto.

Referring to FIGS. 5 and 6, the electronic device 10 may include the display panel 11, a component 18, and a housing 19. In one or more embodiments, the display panel 11 and the component 18 may be accommodated in the housing 19. In one or more embodiments, the component 18 may include a part or a whole entity of at least one of the input module 15, the non-image output module 16, or the communication module 17 described above (see FIG. 1).

The electronic device 10 may have a substantially rectangular shape on a plane. For example, the electronic device 10 may have a rectangular shape having a short side in an x-axis direction, and a long side in a y-axis direction as shown in FIG. 5. A corner where the short side in the x-axis direction and the long side in the y-axis direction meet each other may have a rounded shape with a curvature (e.g., preset curvature) or may form a right angle. A plane shape of the electronic device 10 is not limited to the rectangular shape and may have a polygonal shape, an elliptical shape, or an irregular shape. A shape of the display panel 11 may at least partially correspond to the shape of the electronic device 10.

The electronic device 10 may include an opening area OA and a display area DA at least partially surrounding the opening area OA. The electronic device 10 may include a middle area MA positioned between the opening area OA and the display area DA. The middle area MA may have a closed loop shape that at least partially (e.g., entirely) surrounds the opening area OA on a plane/in plan view. The electronic device 10 may include a peripheral area PA arranged outside the display area DA. The peripheral area PA may at least partially (e.g., entirely) surround the display area DA (e.g., in plan view).

The opening area OA may be positioned inside the display area DA. In one or more embodiments, as shown in FIG. 5, the opening area OA may be arranged at the center of the upper part of the display area DA. In one or more embodiments, the opening area OA may be variously arranged as being arranged at the upper left of the display area DA or at the upper right of the display area DA. FIG. 5 illustrates one or more embodiments having one opening area OA, however, in one or more embodiments, the opening area OA may be provided in plural.

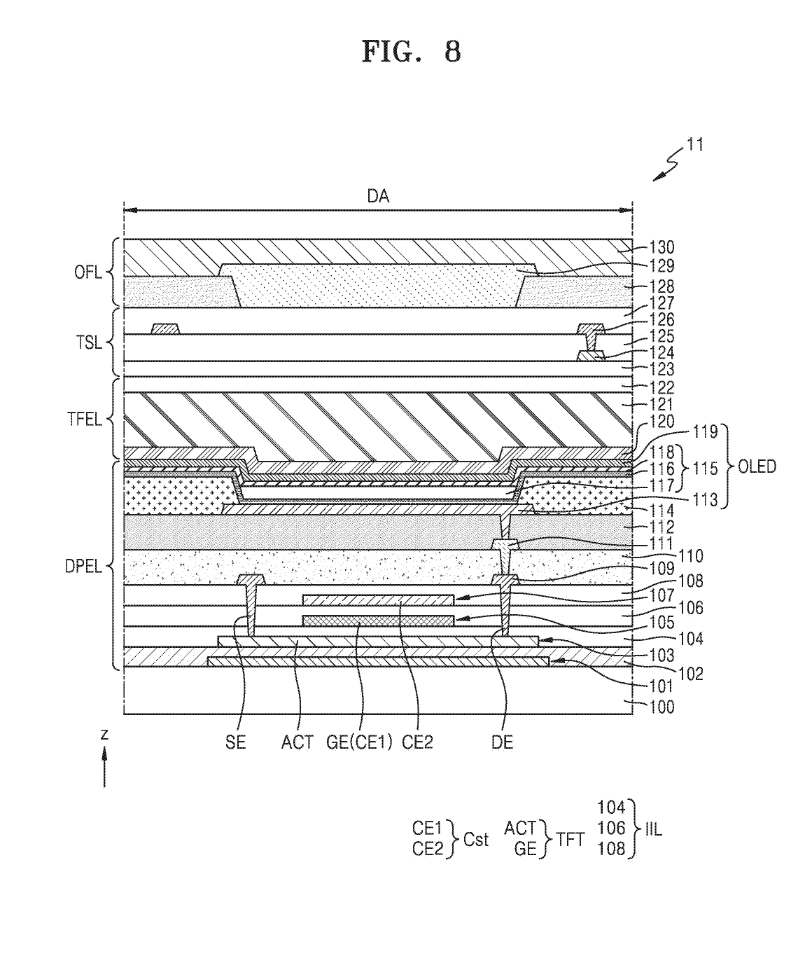

As the electronic device 10 includes the display panel 11, it may be understood that the display panel 11 includes the opening area OA, the display area DA, the middle area MA, and the peripheral area PA. Alternatively, as the display panel 11 includes a substrate 100 (see FIG. 8), it may be understood that the substrate 100 includes the opening area OA, the display area DA, the middle area MA, and the peripheral area PA. Alternatively, it may be understood that the opening area OA, the display area DA, the middle area MA, and the peripheral area PA are defined in the substrate 100.

The electronic device 10 may display an image via a plurality of pixels PX arranged in the display area DA. Alternatively, it may be understood that the display panel 11 displays the image via the plurality of pixels PX arranged in the display area DA. The plurality of pixels PX of the electronic device 10 and the display panel 11 may each include a light-emitting diode as a display element for displaying an image and a pixel circuit for driving the light-emitting diode.

A display element layer DPEL may include the display element provided in plural. The display element may include the light-emitting diode, e.g., an organic light-emitting diode including an organic emission layer. In one or more other embodiments, the light-emitting diode may be an inorganic light-emitting diode including an inorganic material. The inorganic light-emitting diode may include a PN junction diode including inorganic semiconductor-based materials. When a voltage is applied to the PN junction diode in a forward direction, holes and electrons may be injected, and energy generated by recombination of the holes and electrons may be converted into light energy to emit light of a color (e.g., preset color). In some embodiments, the display element layer DPEL may include a quantum-dot light-emitting diode. For example, an emission layer of the display element layer DPEL may include an organic material, may include an inorganic material, may include quantum dots, may include an organic material and quantum dots, or may include an inorganic material and quantum dots.

A thin-film encapsulation layer TFEL may be arranged on the display element layer DPEL so as to protect the display element layer DPEL from exterior factors including moisture, foreign substances, etc. The thin-film encapsulation layer TFEL may entirely cover the display element layer DPEL. The thin-film encapsulation layer TFEL may include at least one of an inorganic encapsulation layer including an inorganic insulating material or an organic encapsulation layer including an organic insulating material.

A touch-sensing layer TSL may obtain coordinate information according to an external input, e.g., a touch event. The touch-sensing layer TSL may include a touch electrode (also referred to as a sensing electrode) and a signal line (also referred to as a trace line) connected to the touch electrode. The touch-sensing layer TSL may be arranged on the thin-film encapsulation layer TFEL. The touch-sensing layer TSL may detect an external input by a mutual-capacitance (cap) scheme and/or a self-cap scheme.

An optical function layer OFL may be arranged on the touch-sensing layer TSL. The optical function layer OFL may include a light-blocking layer for blocking reflection of external light, which may occur in layers arranged therebelow. The optical function layer OFL may include a color filter capable of increasing an efficiency of the display element of the display element layer DPEL, e.g., the light-emitting diode.

In one or more embodiments, a cover window may be arranged on the optical function layer OFL, thereby covering the display panel 11. The cover window may be coupled to the display panel 11 via an optical clear adhesive (OCA).

The cover window may include a glass material or a plastic material. The glass material may include Samsung Ultra Thin Glass^{®} (Samsung Ultra Thin Glass^{®} being a registered trademark of SAMSUNG ELECTRONICS CO., LTD. (limited company (ltd.); REPUBLIC OF KOREA). The plastic material may include polyethersulfone, polyacrylate, polyetherimide, polyethylene naphthalate, polyethylene terephthalate, polyphenylene sulfide, polyarylate, polyimide, polycarbonate, or cellulose acetate propionate.

In one or more embodiments, an adhesive layer may be arranged between two layers selected from among the aforementioned various layers.

To increase transmittance of the opening area OA, the display panel 11 may include a penetrating opening 11OP that penetrates through some of layers configuring the display panel 11. The penetrating opening 11OP may include openings that respectively penetrate through the display element layer DPEL, the thin-film encapsulation layer TFEL, the touch-sensing layer TSL, and the optical function layer OFL. The openings of the display element layer DPEL, the thin-film encapsulation layer TFEL, the touch-sensing layer TSL, and the optical function layer OFL may overlap and form the penetrating opening 11OP of the display panel 11.

The component 18 may be arranged in the opening area OA. The component 18 may overlap the penetrating opening 11OP of the display panel 11. The component 18 may be arranged below the display panel 11, e.g., at or below a rear surface of the display panel 11. The opening area OA may be a component area (e.g., a sensor area, a camera area, a speaker area, etc.) in which the component 18 for adding various functions to the electronic device 10 is positioned.

The component 18 may include an electronic component. For example, the component 18 may be the electronic component that uses light or sound. For example, the electronic component may include a sensor, such as an infrared sensor configured to use light, a camera configured to capture an image by receiving light, a sensor configured to measure a distance by outputting and detecting light or sound or to recognize a fingerprint, a small lamp configured to output light, a speaker configured to output sound, etc. The electronic component configured to use light may use light with various wavelength ranges such visible light, infrared light, ultraviolet light, etc. The opening area OA corresponds to an area through which light and/or sound that is output from the component 18 to the outside or travels from the outside to the electronic component passes.

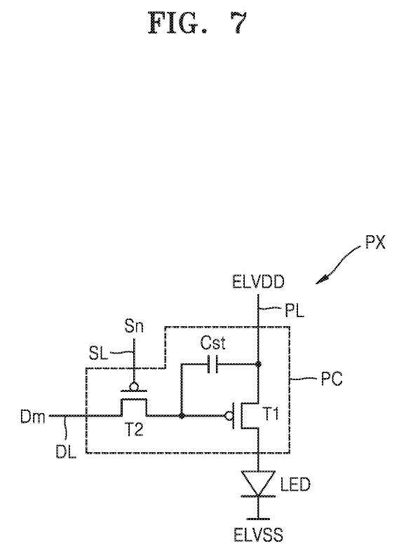

FIG. 7 is a circuit diagram schematically illustrating a light-emitting diode and a pixel circuit connected to the light-emitting diode, which are included in a pixel of a display panel, according to one or more embodiments.

Referring to FIG. 7, a pixel circuit PC may be connected to a light-emitting diode LED, and thus, may implement light-emission of pixels PX. In one or more embodiments, the light-emitting diode LED may include an organic light-emitting diode. The pixel circuit PC may include a first transistor T1, a second transistor T2, and a storage capacitor Cst. In one or more embodiments, the first transistor T1 may be a driving transistor, and the second transistor T2 may be a switching transistor. The second transistor T2 is connected to a scan line SL and a data line DL, and transmits a data signal Dm, which is input via the data line DL, to the first transistor T1, according to a scan signal Sn input via the scan line SL.

The storage capacitor Cst is connected to the second transistor T2 and a driving power line PL, and stores a voltage corresponding to a difference between a voltage received from the second transistor T2 and a driving voltage ELVDD supplied to the driving power line PL.

The first transistor T1 may be connected to the driving power line PL and the storage capacitor Cst, and may control driving current flowing the driving power line PL to the light-emitting diode LED, in response to a value of the voltage stored in the storage capacitor Cst. The light-emitting diode LED may emit light having a luminance (e.g., preset luminance) caused by the driving current.

The pixel circuit PC is not limited to the number and circuit designs of thin-film transistors and storage capacitors described with reference to FIG. 7, and the number and circuit designs may be variously changeable.

FIG. 8 is a cross-sectional view of a display area of a display panel according to one or more embodiments.

Referring to FIG. 8, the display element layer DPEL, the thin-film encapsulation layer TFEL, the touch-sensing layer TSL, and the optical function layer OFL may be sequentially arranged on the substrate 100.

The display element layer DPEL may include a light-emitting diode LED and a thin-film transistor TFT connected to the light-emitting diode LED. In one or more embodiments, FIG. 8 may schematically illustrate a part of the pixel circuit PC described with reference to FIG. 7. For example, the thin-film transistor TFT connected to the light-emitting diode LED may correspond to a transistor, e.g., the first transistor T1, which is connected to the light-emitting diode LED from among the transistors shown in FIG. 7.

The substrate 100 may include a glass material or polymer resin. In one or more embodiments, the substrate 100 may include a stack structure of a base layer including the polymer resin and a barrier layer including an inorganic insulating material. The polymer resins may include at least one of materials including polyethersulfone, polyarylate, polyetherimide, polyethylene naphthalate, polyethylene terephthalate, polyphenylene sulfide, polyimide, polycarbonate, cellulose triacetate, or cellulose acetate propionate. The inorganic insulating material may include at least one of materials including silicon dioxide (SiO₂) or silicon nitride (SiNₓ).

A first conductive layer 101 may be arranged on the substrate 100. In one or more embodiments, the first conductive layer 101 may include a power line and/or a signal line. In one or more embodiments, the first conductive layer 101 may be arranged below a semiconductor layer 103, e.g., an active pattern ACT, and thus, may reduce or prevent delivery of wavelength and/or light caused by the bottom of the display panel 11 to the active pattern ACT. In one or more embodiments, the first conductive layer 101 may include metal (e.g., metal having a light-blocking characteristic). In one or more embodiments, the first conductive layer 101 may include at least one of materials including aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), or copper (Cu), and may be a single layer or layers.

A first insulating layer 102 may be arranged on the first conductive layer 101. The first insulating layer 102 may entirely cover the first conductive layer 101. The first insulating layer 102 may have a flat surface. The first insulating layer 102 may include an inorganic insulating material. In one or more embodiments, the first insulating layer 102 may include at least one of materials including silicon dioxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂), and may be a single layer or layers. In one or more embodiments, the first insulating layer 102 may be a buffer layer.

A thin-film transistor TFT and an inorganic insulating layer IIL may be arranged on the first insulating layer 102. The inorganic insulating layer IIL may include a plurality of layers, and each of elements of the thin-film transistor TFT may be arranged between two of layers of the inorganic insulating layer IIL. The thin-film transistor TFT may include the active pattern ACT and a gate electrode GE. The inorganic insulating layer IIL may include a second insulating layer 104, a third insulating layer 106, and a fourth insulating layer 108.

The semiconductor layer 103 may be arranged on the first insulating layer 102. The semiconductor layer 103 may include the active pattern ACT. The active pattern ACT may include a source region overlapping a source electrode SE, a drain region overlapping a drain electrode DE, and a channel region between the source region and the drain region. The channel region may overlap the gate electrode GE. The source region and the drain region may be regions doped with impurities (e.g., dopant).

The second insulating layer 104 may be arranged on the semiconductor layer 103. The second insulating layer 104 may cover the semiconductor layer 103, e.g., the active pattern ACT. The second insulating layer 104 may include an inorganic insulating material. In one or more embodiments, the second insulating layer 104 may include at least one of materials including silicon dioxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂), and may be a single layer or layers. In one or more embodiments, the second insulating layer 104 may be a first gate-insulating layer.

The storage capacitor Cst may be arranged on the second insulating layer 104. The storage capacitor Cst may include a first capacitor electrode CE1 and a second capacitor electrode CE2. The first capacitor electrode CE1 and the second capacitor electrode CE2 may overlap each other. The second capacitor electrode CE2 may be arranged on the first capacitor electrode CE1.

A second conductive layer 105 may be arranged on the second insulating layer 104. The second conductive layer 105 may include the gate electrode GE of the thin-film transistor TFT and the first capacitor electrode CE1 of the storage capacitor Cst. In one or more embodiments, the gate electrode GE and the first capacitor electrode CE1 may be provided as an integrated element as shown in FIG. 8. In one or more embodiments, the gate electrode GE and the first capacitor electrode CE1 may be separately provided. In one or more embodiments, the second conductive layer 105 may include at least one of materials including aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), or copper (Cu), and may be a single layer or layers.

The third insulating layer 106 may be arranged on the second conductive layer 105. The third insulating layer 106 may cover the second conductive layer 105, e.g., the gate electrode GE and the first capacitor electrode CE1. The third insulating layer 106 may include an inorganic insulating material. In one or more embodiments, the third insulating layer 106 may include at least one of materials including silicon dioxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂), and may be a single layer or layers. In one or more embodiments, the third insulating layer 106 may be a second gate-insulating layer.

A third conductive layer 107 may be arranged on the third insulating layer 106. The third conductive layer 107 may include the second capacitor electrode CE2. The second capacitor electrode CE2 may overlap the first capacitor electrode CE1. In one or more embodiments, the third conductive layer 107 may include at least one of materials including aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), or copper (Cu), and may be a single layer or layers.

The fourth insulating layer 108 may be arranged on the third conductive layer 107. The fourth insulating layer 108 may cover the third conductive layer 107, e.g., the second capacitor electrode CE2. The fourth insulating layer 108 may include an inorganic insulating material. In one or more embodiments, the fourth insulating layer 108 may include at least one of materials including silicon dioxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂), and may be a single layer or layers. In one or more embodiments, the fourth insulating layer 108 may be an intermediate insulating layer.

A fourth conductive layer 109 may be arranged on the fourth insulating layer 108. The fourth conductive layer 109 may include a source electrode SE and a drain electrode DE. The source electrode SE may overlap the source region of the active pattern ACT. The source electrode SE may be connected to the active pattern ACT (e.g., the source region) via an opening defined in the inorganic insulating layer IIL (e.g., the second, third, and fourth insulating layers 104, 106, and 108). The drain electrode DE may overlap the drain region of the active pattern ACT. The drain electrode DE may be connected to the active pattern ACT (e.g., the drain region) via an opening defined in the inorganic insulating layer IIL (e.g., the second, third, and fourth insulating layers 104, 106, and 108). In one or more embodiments, the fourth conductive layer 109 may include at least one of materials including aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), or copper (Cu), and may be a single layer or layers.

FIG. 8 illustrates one or more embodiments in which each of the second, third, and fourth insulating layers 104, 106, and 108 has a flat surface, but the disclosure is not limited thereto, and the second, third, and fourth insulating layers 104, 106, and 108 may have top surface shapes (e.g., uneven shapes) that respectively correspond to shapes of layers arranged therebelow.

A fifth insulating layer 110 may be arranged on the fourth conductive layer 109. The fifth insulating layer 110 may cover the fourth conductive layer 109, e.g., the source electrode SE and the drain electrode DE. The fifth insulating layer 110 may have a flat surface. The fifth insulating layer 110 may include an organic insulating material. In one or more embodiments, the fifth insulating layer 110 may include at least one of materials including general-purpose polymer, such as benzocyclobutene, polyimide, hexamethyldisiloxane, polymethylmethacrylate, or polystyrene, polymer derivatives having a phenolic group, acrylic polymer, imide-based polymer, aryl ether-based polymer, amide-based polymer, fluorine-based polymer, p-xylene-based polymer, or vinyl alcohol-based polymer, and may be a single layer or layers. In one or more embodiments, the fifth insulating layer 110 may be a first via layer.

A fifth conductive layer 111 may be arranged on the fifth insulating layer 110. The fifth conductive layer 111 may include a contact metal that connects the fourth conductive layer 109, e.g., the drain electrode DE, to a first electrode 113 of the light-emitting diode LED. The fifth conductive layer 111 may include a gate electrode of another transistor, a signal line, a power line, etc. In one or more embodiments, the fifth conductive layer 111 may include at least one of materials including aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), or copper (Cu), and may be a single layer or layers.

A sixth insulating layer 112 may be arranged on the fifth conductive layer 111. The sixth insulating layer 112 may cover the fifth conductive layer 111. The sixth insulating layer 112 may have a flat surface. The sixth insulating layer 112 may include an organic insulating material. In one or more embodiments, the sixth insulating layer 112 may include at least one of materials including general-purpose polymer, such as benzocyclobutene, polyimide, hexamethyldisiloxane, polymethylmethacrylate, or polystyrene, polymer derivatives having a phenolic group, acrylic polymer, imide-based polymer, aryl ether-based polymer, amide-based polymer, fluorine-based polymer, p-xylene-based polymer, or vinyl alcohol-based polymer, and may be a single layer or layers. In one or more embodiments, the sixth insulating layer 112 may be a second via layer.

The light-emitting diode LED may be arranged on the sixth insulating layer 112. The light-emitting diode LED may include the first electrode 113 and a second electrode 119 that face each other, and an intermediate layer 115 between the first electrode 113 and a second electrode 119. In one or more embodiments, the first electrode 113 of the light-emitting diode LED may correspond to an anode, and the second electrode 119 may correspond to a cathode.

The first electrode 113 of the light-emitting diode LED may be arranged on the sixth insulating layer 112. The first electrode 113 may be connected to the fifth conductive layer 111 via an opening defined in the sixth insulating layer 112. The first electrode 113 may be connected (e.g., electrically) to the thin-film transistor TFT via the fifth conductive layer 111 and the drain electrode DE. The first electrode 113 may include a conductive oxide including indium tin oxide (ITO), indium zinc oxide (IZO), zinc oxide (ZnO), indium oxide (In₂O₃), indium gallium oxide (IGO), or aluminum zinc oxide (AZO). The first electrode 113 may include a reflection layer including silver (Ag), magnesium (Mg), aluminum (Al), platinum (Pt), palladium (Pd), gold (Au), nickel (Ni), neodymium (Nd), iridium (Ir), chromium (Cr), or any compound thereof. A configuration and material of the first electrode 113 are not limited thereto, and thus, may vary.

A pixel-defining layer 114 may be arranged on the sixth insulating layer 112. The pixel-defining layer 114 may cover a side (e.g., an edge) of the first electrode 113. In another expression, the pixel-defining layer 114 may be open to expose a center part of the first electrode 113. A size and a shape of an emission area of the light-emitting diode LED may be determined by the opening of the pixel-defining layer 114. In one or more embodiments, the pixel-defining layer 114 may include an organic insulating material. In one or more embodiments, the pixel-defining layer 114 may include at least one of materials including general-purpose polymer, such as benzocyclobutene, polyimide, hexamethyldisiloxane, polymethylmethacrylate, or polystyrene, polymer derivatives having a phenolic group, acrylic polymer, imide-based polymer, aryl ether-based polymer, amide-based polymer, fluorine-based polymer, p-xylene-based polymer, or vinyl alcohol-based polymer, and may be a single layer or layers.

The intermediate layer 115 may be arranged on the first electrode 113. The intermediate layer 115 may include first and second common layers 116 and 118 arranged on the pixel-defining layer 114, and an emission layer 117 arranged in the opening of the pixel-defining layer 114. The first common layer 116 may be arranged on the first electrode 113. In one or more embodiments, the first common layer 116 may be arranged on the pixel-defining layer 114, the emission layer 117 may be arranged above the first common layer 116 and in the opening of the pixel-defining layer 114, and the second common layer 118 may be arranged on the emission layer 117 so as to cover the emission layer 117. In another expression, the emission layer 117 may be arranged in the opening of the pixel-defining layer 114 and may be provided between the first common layer 116 and the second common layer 118.

The emission layer 117 may include a small-molecular material or a polymer material that emits light having a corresponding color. The first common layer 116 may include an electron transport layer (ETL) and/or an electron injection layer (EIL). The second common layer 118 may include a hole transport layer (HTL) and/or a hole injection layer (HIL). In some embodiments, the first common layer 116 or the second common layer 118 may be omitted. In some embodiments, positions of first common layer 116 and the second common layer 118 may be interchanged.

The second electrode 119 may be arranged on the intermediate layer 115. For example, the second electrode 119 may be arranged on the second common layer 118. The second electrode 119 may be arranged to entirely cover the intermediate layer 115. The second electrode 119 may include a conductive material. For example, the second electrode 119 may include a transparent layer (or, a semi-transparent layer) including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or any alloy thereof. Alternatively, on the transparent layer (or, the semi-transparent layer) including the aforementioned material, the second electrode 119 may further include a layer including oxide, such as indium tin oxide (ITO), indium zinc oxide (IZO), zinc oxide (ZnO), or indium oxide (In₂O₃).

The thin-film encapsulation layer TFEL may be arranged on the second electrode 119 and may entirely cover the light-emitting diode LED. The thin-film encapsulation layer TFEL may include at least one inorganic layer and at least one organic layer. In one or more embodiments, the thin-film encapsulation layer TFEL may include a first inorganic encapsulation layer 120, a second inorganic encapsulation layer 122, and an organic encapsulation layer 121 between the first inorganic encapsulation layer 120 and the second inorganic encapsulation layer 122. In one or more embodiments, the first inorganic encapsulation layer 120 and the second inorganic encapsulation layer 122 may have top surface shapes (e.g., uneven shapes) that respectively correspond to shapes of layers arranged therebelow. In one or more embodiments, the organic encapsulation layer 121 may have a flat surface.

The first inorganic encapsulation layer 120 and/or the second inorganic encapsulation layer 122 may include at least one of materials including silicon dioxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂), and may be a single layer or layers. The organic encapsulation layer 121 may include a polymer-based material. The polymer-based material may include a silicone-based resin, an acryl-based resin, an epoxy-based resin, polyimide, and/or polyethylene.

The touch-sensing layer TSL may be arranged on the thin-film encapsulation layer TFEL. The touch-sensing layer TSL may include a touch electrode layer for detecting an external input, e.g., a touch event, and a touch-insulating layer between touch electrode layers. The touch-sensing layer TSL may include a first touch-insulating layer 123, a first touch electrode layer 124, a second touch-insulating layer 125, a second touch electrode layer 126, and a third touch-insulating layer 127.

The first touch-insulating layer 123 may be arranged on the thin-film encapsulation layer TFEL, e.g., on the second inorganic encapsulation layer 122 of the thin-film encapsulation layer TFEL. The first touch electrode layer 124 may be arranged on the first touch-insulating layer 123. The second touch-insulating layer 125 may be arranged on the first touch electrode layer 124 so as to cover the first touch electrode layer 124. The second touch electrode layer 126 may be arranged on the second touch-insulating layer 125. The third touch-insulating layer 127 may be arranged on the second touch electrode layer 126 so as to cover the second touch electrode layer 126. The second touch electrode layer 126 may be connected to the first touch electrode layer 124 via an opening defined in the second touch-insulating layer 125. In one or more embodiments, the second touch electrode layer 126 may include a sensing electrode, and the first touch electrode layer 124 may include a bridge electrode.

In one or more embodiments, the first touch-insulating layer 123 may include an inorganic insulating material. In one or more embodiments, the first touch-insulating layer 123 may include at least one of materials including silicon dioxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂), and may be a single layer or layers.

In one or more embodiments, the second touch-insulating layer 125 and the third touch-insulating layer 127 may each include an organic insulating material. In one or more embodiments, the second touch-insulating layer 125 and/or the third touch-insulating layer 127 may each include an acryl-based organic insulating material. In one or more embodiments, the second touch-insulating layer 125 and/or the third touch-insulating layer 127 may have a flat surface.

All portions of the first touch electrode layer 124 and the second touch electrode layer 126 may not overlap the emission area of the light-emitting diode LED. In one or more embodiments, the first touch electrode layer 124 and the second touch electrode layer 126 may not overlap the emission layer 117 of the light-emitting diode LED. In another expression, the first touch electrode layer 124 and the second touch electrode layer 126 may each have an opening overlapping the emission area or the emission layer 117 of the light-emitting diode LED.

The optical function layer OFL may be arranged on the touch-sensing layer TSL. The optical function layer OFL may include a light-blocking layer 128, a color filter 129, and an over-coating layer 130. The over-coating layer 130 may cover the light-blocking layer 128 and the color filter 129 and may have a flat surface.

The light-blocking layer 128 may be arranged on the touch-sensing layer TSL, e.g., the third touch-insulating layer 127. The light-blocking layer 128 may include a light-blocking material, and may cover the first and second touch electrode layers 124 and 126, thereby reducing or preventing reflection of external light by the first and second touch electrode layers 124 and 126 and viewed by a user. An aspect of the light-blocking layer 128 is not limited thereto, and the light-blocking layer 128 may provide various aspects. The light-blocking layer 128 may be open to allow light emitted from the light-emitting diode LED to pass therethrough. The opening of the light-blocking layer 128 may overlap the light-emitting diode LED, e.g., the emission layer 117.

The color filter 129 may be arranged on the light-blocking layer 128. The color filter 129 may overlap the opening of the light-blocking layer 128, and a part of the color filter 129 may be arranged in the opening of the light-blocking layer 128. The color filter 129 may transmit light having a color (or wavelength range) corresponding to light emitted from the emission layer 117 of the light-emitting diode LED. For example, when the emission layer 117 of the light-emitting diode LED emits red light, the color filter 129 may be arranged to transmit light having a red wavelength range.

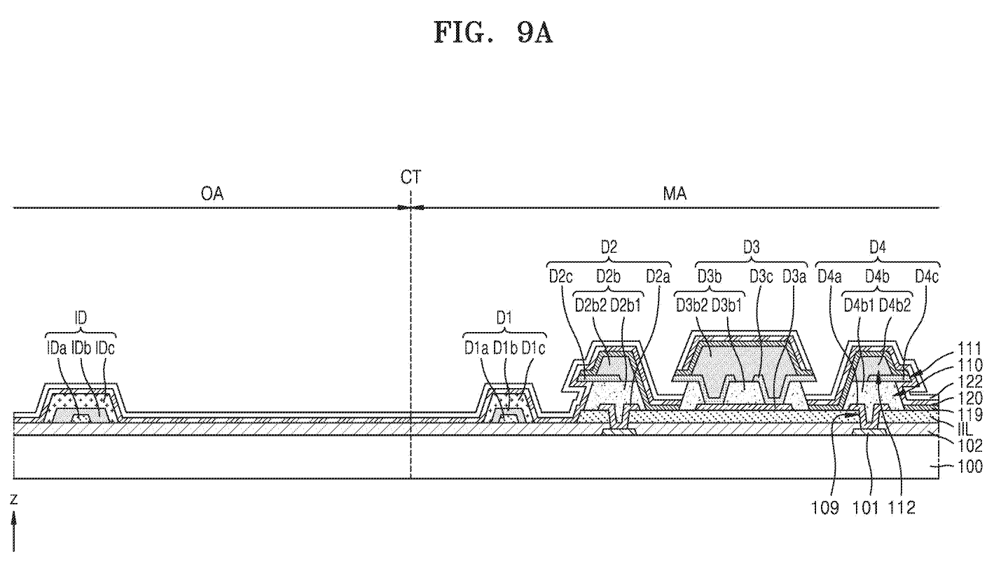

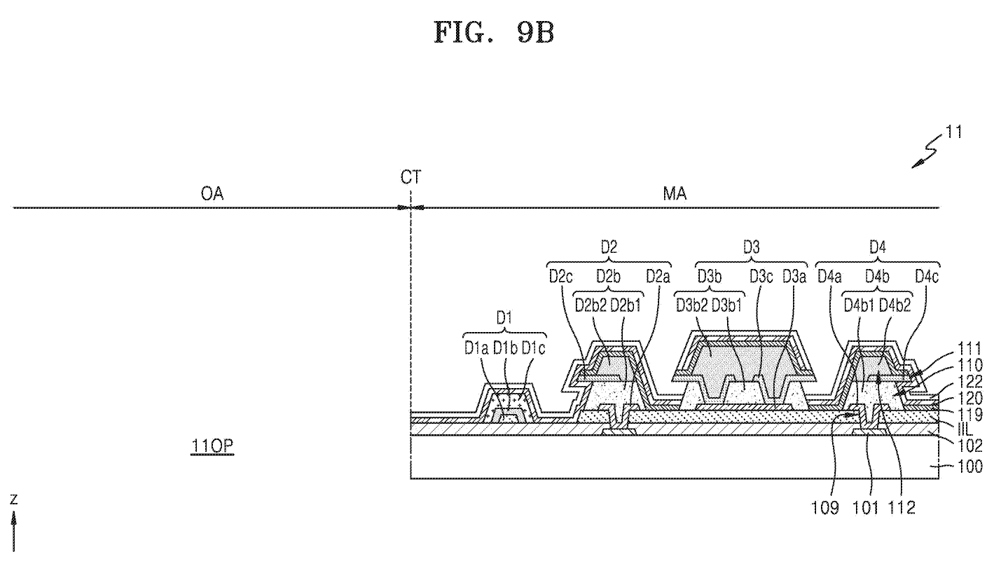

FIGS. 9A and 9B are cross-sectional views of the display panel 11 according to one or more embodiments.

FIG. 9A illustrates one or more embodiments in which the opening area OA is not cut, and FIG. 9B illustrates one or more embodiments in which the opening area OA is cut. The one or more embodiments corresponding to FIG. 9A may be understood as a semi-finished product of the display panel 11, and the one or more embodiments corresponding to FIG. 9B may be understood as the display panel 11.

The method of manufacturing a display panel according to one or more embodiments may include a process of cutting the substrate 100 and a plurality of layers on the substrate 100 along a cutting line CT. The cutting line CT may indicate a boundary between the opening area OA and the middle area MA. Alternatively, the boundary between the opening area OA and the middle area MA may be defined by the cutting line CT. The method of manufacturing a display panel according to one or more embodiments may include a process of removing a part of the display panel 11 corresponding to the opening area OA. Accordingly, in FIG. 9B, the penetrating opening 11OP is defined in the opening area OA. FIG. 9A illustrates one or more embodiments before cutting (and removing), and FIG. 9B illustrates one or more embodiments after cutting (and removing), and thus, it may be understood that FIGS. 9A and 9B are cross-sectional views illustrating processes of the method of manufacturing a display panel according to one or more embodiments.

The method of manufacturing a display panel according to one or more embodiments may include a process of coupling the display panel 11 to the housing 19 (see FIG. 6), the display panel 11 being formed via the cutting process (shown in FIG. 9B, as an example).

Referring to FIGS. 9A and 9B, the first insulating layer 102 may be arranged on the substrate 100. In one or more embodiments, the first insulating layer 102 may be omitted. A first dam D1, a second dam D2, a third dam D3, a fourth dam D4, and an inner dam ID may be arranged on the first insulating layer 102.

The inner dam ID may be arranged in the opening area OA. Therefore, the inner dam ID may be removed in the cutting process and the removing process described above, and FIG. 9B does not illustrate the inner dam ID.

The first dam D1, the second dam D2, the third dam D3, and the fourth dam D4 may be arranged in the middle area MA. The first dam D1, the second dam D2, the third dam D3, and the fourth dam D4 may be sequentially arranged in a direction away from the opening area OA. For example, in a relation between the first dam D1 and the second dam D2, it may be understood that the first dam D1 may be arranged between the second dam D2 and the opening area OA, and the second dam D2 may be arranged between the first dam D1 and the display area DA (see FIG. 5).

The first dam D1 may be arranged on the first insulating layer 102. The first dam D1 may include two or more selected from an organic part including an organic insulating material, an inorganic part including an inorganic insulating material, or a metal part including metal. In one or more embodiments, the first dam D1 may include a first inorganic part D1a, a first-1 organic part D1b, and a first-2 organic part D1c.

In one or more embodiments, the first inorganic part D1a may be arranged on the first insulating layer 102. In one or more embodiments, the first inorganic part D1a may include the same material as the inorganic insulating layer IIL. In one or more embodiments, the first inorganic part D1a and the inorganic insulating layer IIL may be formed in the same process. In one or more embodiments, it may be understood that the first inorganic part D1a is a part of the inorganic insulating layer IIL.

In one or more embodiments, the first-1 organic part D1b may be arranged on the first inorganic part D1a. In one or more embodiments, the first-1 organic part D1b may entirely cover the first inorganic part D1a. In one or more embodiments, the first-1 organic part D1b may include the same material as the sixth insulating layer 112. In one or more embodiments, the first-1 organic part D1b and the sixth insulating layer 112 may be formed in the same process. In one or more embodiments, it may be understood that the first-1 organic part D1b is a part of the sixth insulating layer 112.

In one or more embodiments, the first-2 organic part D1c may be arranged on the first-1 organic part D1b. In one or more embodiments, the first-2 organic part D1c may entirely cover the first-1 organic part D1b. In one or more embodiments, the first-2 organic part D1c may include the same material as the pixel-defining layer 114 (see FIG. 8). In one or more embodiments, the first-2 organic part D1c and the pixel-defining layer 114 may be formed in the same process. In one or more embodiments, it may be understood that the first-2 organic part D1c is a part of the pixel-defining layer 114.

The second dam D2 may be arranged on the inorganic insulating layer IIL extending into the middle area MA. In one or more embodiments, the second dam D2 may include a second-1 metal part D2a, a second organic part D2b, and a second-2 metal part D2c. The second organic part D2b may include a second-1 organic part D2b1 and a second-2 organic part D2b2.

The second-1 metal part D2a may be arranged on the inorganic insulating layer IIL. In one or more embodiments, the second-1 metal part D2a may be connected to the first conductive layer 101 via the opening defined in the inorganic insulating layer IIL and the first insulating layer 102. In one or more embodiments, the second-1 metal part D2a may include the same material as the fourth conductive layer 109. In one or more embodiments, the second-1 metal part D2a and the fourth conductive layer 109 may be formed in the same process. In one or more embodiments, it may be understood that the second-1 metal part D2a is a part of the fourth conductive layer 109.

In one or more embodiments, the second-1 organic part D2b1 may be arranged on the second-1 metal part D2a. In one or more embodiments, the second-1 organic part D2b1 may entirely cover the second-1 metal part D2a. In one or more embodiments, the second-1 organic part D2b1 may include the same material as the fifth insulating layer 110. In one or more embodiments, the second-1 organic part D2b1 and the fifth insulating layer 110 may be formed in the same process. In one or more embodiments, it may be understood that the second-1 organic part D2b1 is a part of the fifth insulating layer 110.

In one or more embodiments, the second-2 organic part D2b2 may be arranged on the second-2 metal part D2c. In one or more embodiments, the second-2 organic part D2b2 may partially cover the second-2 metal part D2c. In one or more embodiments, the second-2 organic part D2b2 may include the same material as the sixth insulating layer 112. In one or more embodiments, the second-2 organic part D2b2 and the sixth insulating layer 112 may be formed in the same process. In one or more embodiments, it may be understood that the second-2 organic part D2b2 is a part of the sixth insulating layer 112.

The second-2 metal part D2c may be arranged on the second organic part D2b (e.g., on a portion of, or embedded within, the second organic part D2b). In one or more embodiments, the second-2 metal part D2c may be arranged between the second-1 organic part D2b1 and the second-2 organic part D2b2. In one or more embodiments, the second-2 metal part D2c may protrude over (e.g., may extend beyond) a side of the second organic part D2b, e.g., a side of the second-1 organic part D2b1 and a side of the second-2 organic part D2b2. In another expression, the second-2 metal part D2c and the second organic part D2b may form an undercut (or, tip) structure. In one or more embodiments, the second-2 metal part D2c may protrude in a direction from the side of the second organic part D2b to, or toward, the opening area OA.

In one or more embodiments, the second electrode 119 may extend to the middle area MA. In one or more embodiments, the second electrode 119 may be disconnected due to the undercut structure formed by the second-2 metal part D2c and the second organic part D2b. In one or more embodiments, the second electrode 119 may be disconnected at an edge of the second-2 metal part D2c protruding over the side of the second organic part D2b. In one or more embodiments, the second electrode 119 may directly contact a top surface of a part of the second-2 metal part D2c that protrudes over the side of the second organic part D2b.

The third dam D3 may be arranged on the inorganic insulating layer IIL extending into the middle area MA. In one or more embodiments, the third dam D3 may include a third-1 metal part D3a, a third organic part D3b, and a third-2 metal part D3c. The third organic part D3b may include a third-1 organic part D3b1 and a third-2 organic part D3b2.

The third-1 metal part D3a may be arranged on the inorganic insulating layer IIL. In one or more embodiments, the third-1 metal part D3a may include the same material as the fourth conductive layer 109. In one or more embodiments, the third-1 metal part D3a and the fourth conductive layer 109 may be formed in the same process. In one or more embodiments, it may be understood that the third-1 metal part D3a is a part of the fourth conductive layer 109.

In one or more embodiments, the third-1 organic part D3b1 may be arranged on the third-1 metal part D3a. In one or more embodiments, the third-1 organic part D3b1 may (e.g., partially) cover the third-1 metal part D3a. In one or more embodiments, the third-1 organic part D3b1 may include the same material as the fifth insulating layer 110. In one or more embodiments, the third-1 organic part D3b1 and the fifth insulating layer 110 may be formed in the same process. In one or more embodiments, it may be understood that the third-1 organic part D3b1 is a part of the fifth insulating layer 110.

In one or more embodiments, the third-2 organic part D3b2 may be arranged on the third-2 metal part D3c. In one or more embodiments, the third-2 organic part D3b2 may partially cover the third-2 metal part D3c. In one or more embodiments, the third-2 organic part D3b2 may include the same material as the sixth insulating layer 112. In one or more embodiments, the third-2 organic part D3b2 and the sixth insulating layer 112 may be formed in the same process. In one or more embodiments, it may be understood that the third-2 organic part D3b2 is a part of the sixth insulating layer 112.

The third-2 metal part D3c may be arranged in (e.g., embedded in) the third organic part D3b. In one or more embodiments, the third-2 metal part D3c may be arranged between the third-1 organic part D3b1 and the third-2 organic part D3b2. In one or more embodiments, the third-2 metal part D3c may protrude over a side of the third organic part D3b, e.g., a side of the third-1 organic part D3b1 and a side of the third-2 organic part D3b2. In another expression, the third-2 metal part D3c and the third organic part D3b may form an undercut (or, tip) structure. In one or more embodiments, the third dam D3 may include two or more third-2 metal parts D3c. In one or more embodiments, one of the third-2 metal parts D3c may protrude in a direction from the side of the third organic part D3b to the opening area OA. In one or more embodiments, another of the third-2 metal parts D3c may protrude in a direction from the side of the third organic part D3b to the display area DA (see FIG. 5). In one or more embodiments, the third-2 metal parts D3c may be connected to the third-1 metal part D3a via an opening defined in the third-1 organic part D3b1.

In one or more embodiments, the second electrode 119 may be disconnected due to the undercut structure formed by the third-2 metal part D3c and the third organic part D3b. In one or more embodiments, the second electrode 119 may be disconnected at an edge of the third-2 metal part D3c protruding over (e.g., extending beyond, in plan view) the side of the third organic part D3b. In one or more embodiments, the second electrode 119 may directly contact a top surface of a part of the third-2 metal part D3c that protrudes over the side of the third organic part D3b.

The fourth dam D4 may be arranged on the inorganic insulating layer IIL extending into the middle area MA. In one or more embodiments, the fourth dam D4 may include a fourth-1 metal part D4a, a fourth organic part D4b, and a fourth-2 metal part D4c. The fourth organic part D4b may include a fourth-1 organic part D4b1 and a fourth-2 organic part D4b2.

The fourth-1 metal part D4a may be arranged on the inorganic insulating layer IIL. In one or more embodiments, the fourth-1 metal part D4a may be connected to the first conductive layer 101 via the opening defined in the inorganic insulating layer IIL and the first insulating layer 102. In one or more embodiments, the fourth-1 metal part D4a may include the same material as the fourth conductive layer 109. In one or more embodiments, the fourth-1 metal part D4a and the fourth conductive layer 109 may be formed in the same process. In one or more embodiments, it may be understood that the fourth-1 metal part D4a is a part of the fourth conductive layer 109.

In one or more embodiments, the fourth-1 organic part D4b1 may be arranged on the fourth-1 metal part D4a. In one or more embodiments, the fourth-1 organic part D4b1 may entirely cover the fourth-1 metal part D4a. In one or more embodiments, the fourth-1 organic part D4b1 may include the same material as the fifth insulating layer 110. In one or more embodiments, the fourth-1 organic part D4b1 and the fifth insulating layer 110 may be formed in the same process. In one or more embodiments, it may be understood that the fourth-1 organic part D4b1 is a part of the fifth insulating layer 110.

In one or more embodiments, the fourth-2 organic part D4b2 may be arranged on the fourth-2 metal part D4c. In one or more embodiments, the fourth-2 organic part D4b2 may partially cover the fourth-2 metal part D4c. In one or more embodiments, the fourth-2 organic part D4b2 may include the same material as the sixth insulating layer 112. In one or more embodiments, the fourth-2 organic part D4b2 and the sixth insulating layer 112 may be formed in the same process. In one or more embodiments, it may be understood that the fourth-2 organic part D4b2 is a part of the sixth insulating layer 112.

The fourth-2 metal part D4c may be arranged in (e.g., embedded in) the fourth organic part D4b. In one or more embodiments, the fourth-2 metal part D4c may be arranged between the fourth-1 organic part D4b1 and the fourth-2 organic part D4b2. In one or more embodiments, the fourth-2 metal part D4c may protrude over a side of (e.g., may extend beyond a side of) the fourth organic part D4b, e.g., a side of the fourth-1 organic part D4b1 and a side of the fourth-2 organic part D4b2. In another expression, the fourth-2 metal part D4c and the fourth organic part D4b may form an undercut (or, tip) structure. In one or more embodiments, the fourth-2 metal part D4c may protrude in a direction from the side of the fourth organic part D4b to the display area DA (see FIG. 5).

In one or more embodiments, the second electrode 119 may be disconnected due to the undercut structure formed by the fourth-2 metal part D4c and the fourth organic part D4b. In one or more embodiments, the second electrode 119 may be disconnected at an edge of the fourth-2 metal part D4c protruding over the side of the fourth organic part D4b. In one or more embodiments, the second electrode 119 may directly contact a top surface of a part of the fourth-2 metal part D4c that protrudes over the side of the fourth organic part D4b.

The inner dam ID may be arranged on the first insulating layer 102. The inner dam ID may have the similar stack structure to the first dam D1. In one or more embodiments, the inner dam ID may include an inner inorganic part IDa, a first inner organic part IDb, and a second inner organic part IDc.

In one or more embodiments, the inner inorganic part IDa may be arranged on the first insulating layer 102. In one or more embodiments, the inner inorganic part IDa may include the same material as the inorganic insulating layer IIL. In one or more embodiments, the inner inorganic part IDa and the inorganic insulating layer IIL may be formed in the same process. In one or more embodiments, it may be understood that the inner inorganic part IDa is a part of the inorganic insulating layer IIL.

In one or more embodiments, the first inner organic part IDb may be arranged on the inner inorganic part IDa. In one or more embodiments, the first inner organic part IDb may entirely cover the inner inorganic part IDa. In one or more embodiments, the first inner organic part IDb may include the same material as the sixth insulating layer 112. In one or more embodiments, the first inner organic part IDb and the sixth insulating layer 112 may be formed in the same process. In one or more embodiments, it may be understood that the first inner organic part IDb is a part of the sixth insulating layer 112.

In one or more embodiments, the second inner organic part IDc may be arranged on the first inner organic part IDb. In one or more embodiments, the second inner organic part IDc may entirely cover the first inner organic part IDb. In one or more embodiments, the second inner organic part IDc may include the same material as the pixel-defining layer 114 (see FIG. 8). In one or more embodiments, the second inner organic part IDc and the pixel-defining layer 114 may be formed in the same process. In one or more embodiments, it may be understood that the second inner organic part IDc is a part of the pixel-defining layer 114.

The first inorganic encapsulation layer 120 and the second inorganic encapsulation layer 122 may extend to the middle area MA and the opening area OA so as to cover the first dam D1, the second dam D2, the third dam D3, the fourth dam D4, and the inner dam ID. In one or more embodiments, the first inorganic encapsulation layer 120 and the second inorganic encapsulation layer 122 may be disconnected due to the undercut structure formed by the third-2 metal part D3c and the third organic part D3b.

The method of manufacturing a display panel according to one or more embodiments may include a process of forming the first dam D1, the second dam D2, the third dam D3, the fourth dam D4, and the inner dam ID. The method of manufacturing a display panel according to one or more embodiments may include a process of cutting the substrate 100, the first inorganic encapsulation layer 120, and the second inorganic encapsulation layer 122 along the cutting line CT. The method of manufacturing a display panel according to one or more embodiments may include a process of removing respective parts of the substrate 100, the first insulating layer 102, the first inorganic encapsulation layer 120, and the second inorganic encapsulation layer 122, and the inner dam ID, which correspond to the opening area OA.

In the aforementioned cutting and removing processes, (in an area near the cutting line CT, for example), delamination between the first insulating layer 102 and the first inorganic encapsulation layer 120, or delamination between the first inorganic encapsulation layer 120 and the second inorganic encapsulation layer 122, may occur. The aforementioned structure of the first dam D1 may provide a strong coupling force with respect to the first insulating layer 102, the first inorganic encapsulation layer 120, and/or the second inorganic encapsulation layer 122, thereby reducing or preventing (or, at least suppressing) occurrence of the delamination.

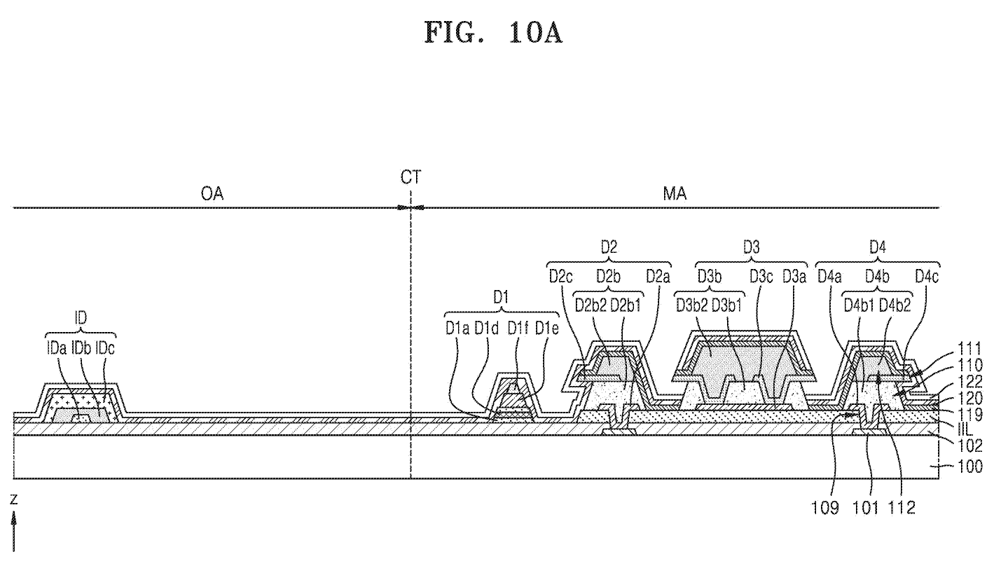

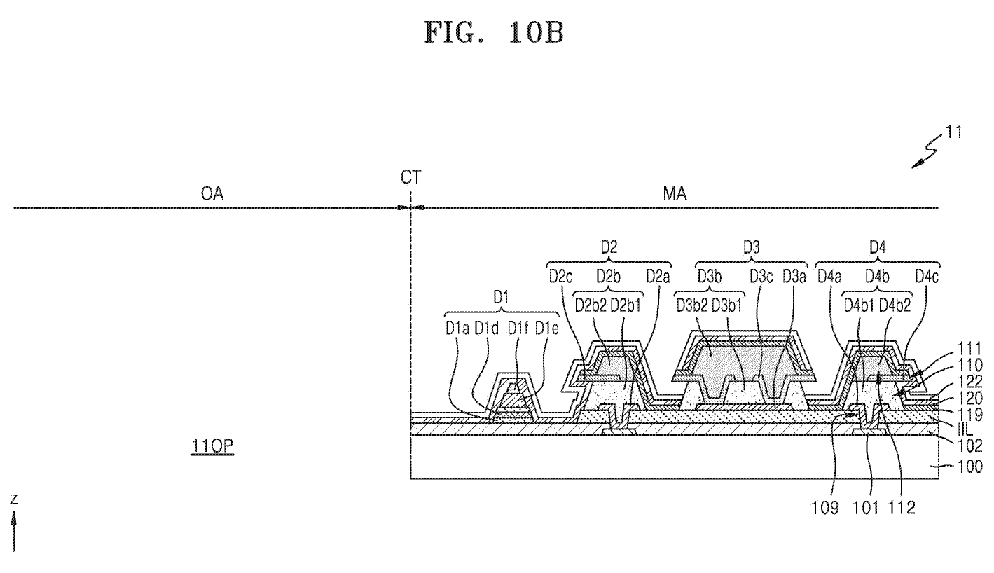

FIGS. 10A and 10B are cross-sectional views of the display panel 11 according to one or more embodiments.

Similar to what is described above with reference to FIGS. 9A and 9B, it may be understood that FIGS. 10A and 10B are cross-sectional views of the display panel 11 and/or cross-sectional views illustrating processes of the method of manufacturing the display panel 11.

In comparison with FIGS. 9A and 9B, referring to FIGS. 10A and 10B, a structure of the first dam D1 is different, and other aspects are substantially similar.

In one or more embodiments, the first dam D1 may include the first inorganic part D1a, a first-1 metal part D1d, a first-2 metal part D1e, and a first-3 metal part D1f.

In one or more embodiments, the first-1 metal part D1d may be arranged in the first inorganic part D1a. In one or more embodiments, the first-1 metal part D1d may include the same material as the second conductive layer 105 (see FIG. 8). In one or more embodiments, the first-1 metal part D1d and the second conductive layer 105 may be formed in the same process. In one or more embodiments, it may be understood that the first-1 metal part D1d is a part of the second conductive layer 105.

In one or more embodiments, unlike to what is shown in FIGS. 10A and 10B, the first-1 metal part D1d may include the same material as the third conductive layer 107 (see FIG. 8). In this case, the first-1 metal part D1d and the third conductive layer 107 may be formed in the same process, and it may be understood that the first-1 metal part D1d is a part of the third conductive layer 107.

In one or more embodiments, the first-2 metal part D1e may be arranged on the first-1 metal part D1d. In one or more embodiments, the first-2 metal part D1e may include the same material as the fourth conductive layer 109. In one or more embodiments, the first-2 metal part D1e and the fourth conductive layer 109 may be formed in the same process. In one or more embodiments, it may be understood that the first-2 metal part D1e is a part of the fourth conductive layer 109. In one or more embodiments, the first-2 metal part D1e may be arranged on the same layer as the second-1 metal part D2a of the second dam D2, the third-1 metal part D3a of the third dam D3, and the fourth-1 metal part D4a of the fourth dam D4. 1

In one or more embodiments, the first-3 metal part D1f may be arranged on the first-2 metal part D1e. In one or more embodiments, the first-3 metal part D1f may include the same material as the fifth conductive layer 111. In one or more embodiments, the first-3 metal part D1f and the fifth conductive layer 111 may be formed in the same process. In one or more embodiments, it may be understood that the first-3 metal part D1f is a part of the fifth conductive layer 111. In one or more embodiments, the first-3 metal part D1f may be arranged on the same layer as the second-2 metal part D2c of the second dam D2, the third-2 metal part D3c of the third dam D3, and the fourth-2 metal part D4c of the fourth dam D4.

The first inorganic encapsulation layer 120 may cover the first dam D1. In one or more embodiments, the first inorganic encapsulation layer 120 may directly contact the first-2 metal part D1e and the first-3 metal part D1f. In one or more embodiments, the first inorganic encapsulation layer 120 may directly contact the first inorganic part D1a and the first-1 metal part D1d.

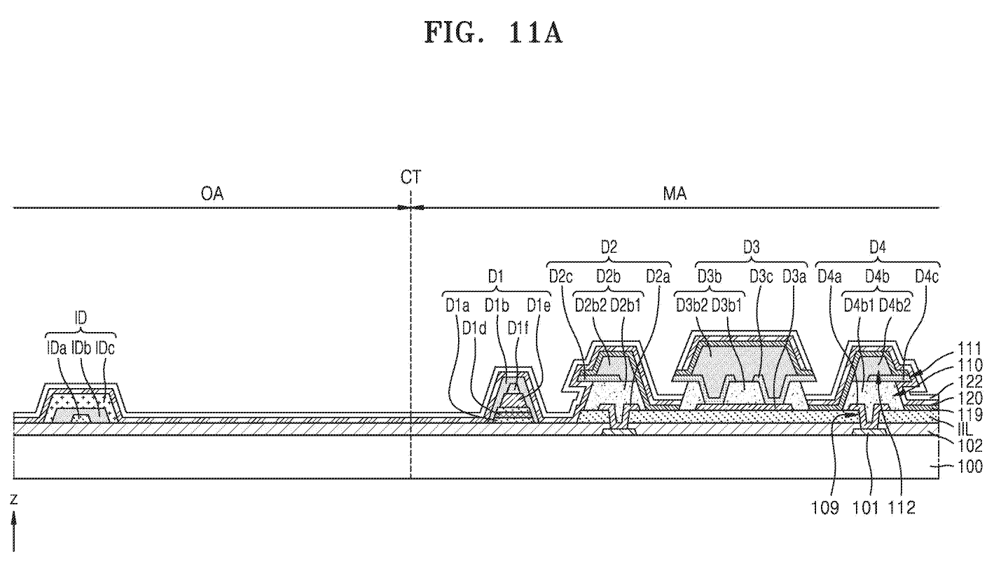

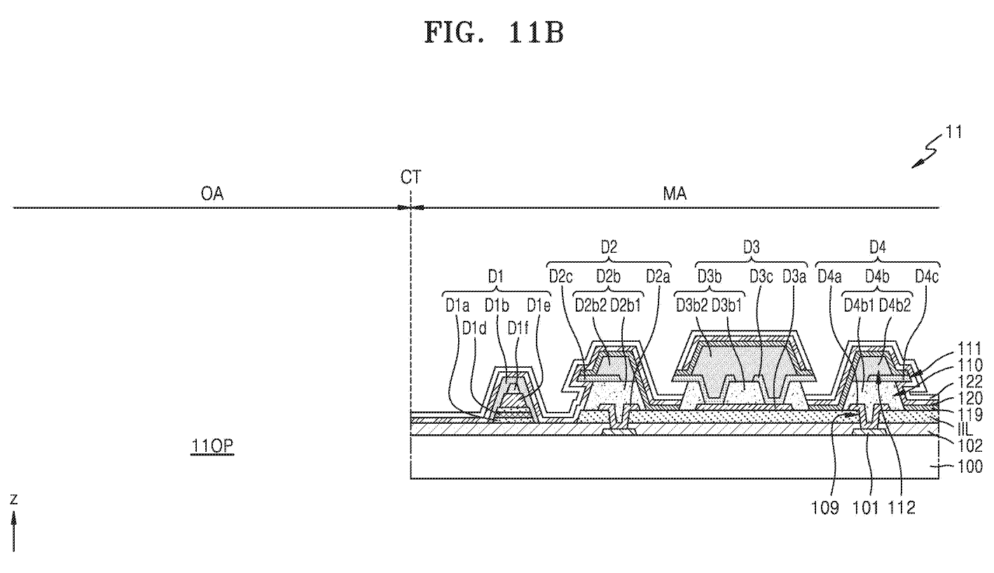

FIGS. 11A and 11B are cross-sectional views of the display panel 11 according to one or more embodiments.

Similar to what is described above with reference to FIGS. 9A and 9B, it may be understood that FIGS. 11A and 11B are cross-sectional views of the display panel 11 and/or cross-sectional views illustrating processes of the method of manufacturing the display panel 11.

In comparison with FIGS. 10A and 10B, referring to FIGS. 11A and 11B, a structure of the first dam D1 is different, and other aspects are substantially similar.

In one or more embodiments, the first dam D1 may include the first inorganic part D1a, the first-1 metal part D1d, the first-2 metal part D1e, the first-3 metal part D1f, and the first-1 organic part D1b.

In one or more embodiments, the first-1 organic part D1b may be arranged on the first-3 metal part D1f. In one or more embodiments, the first-1 organic part D1b may entirely cover the first inorganic part D1a, the first-1 metal part D1d, the first-2 metal part D1e, the first-3 metal part D1f. In one or more embodiments, the first-1 organic part D1b may include the same material as the sixth insulating layer 112. In one or more embodiments, the first-1 organic part D1b and the sixth insulating layer 112 may be formed in the same process. In one or more embodiments, it may be understood that the first-1 organic part D1b is a part of the sixth insulating layer 112.

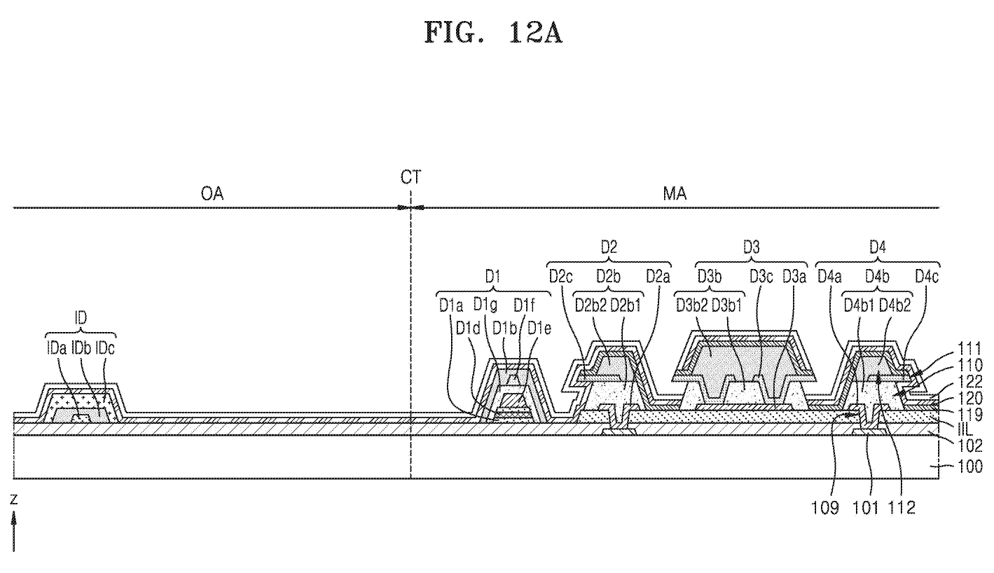

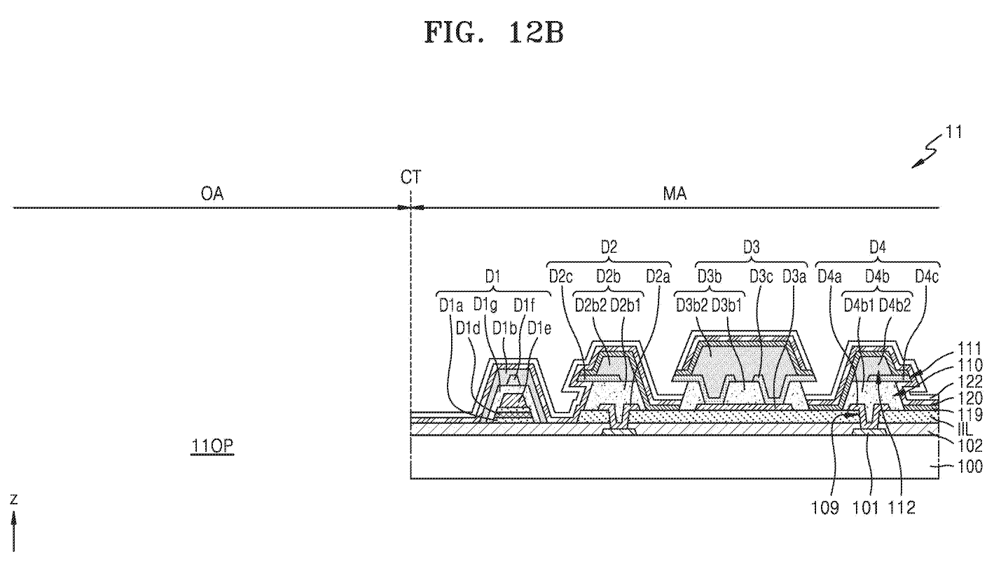

FIGS. 12A and 12B are cross-sectional views of the display panel 11 according to one or more embodiments.

Similar to what is described above with reference to FIGS. 9A and 9B, it may be understood that FIGS. 12A and 12B are cross-sectional views of the display panel 11 and/or cross-sectional views illustrating processes of the method of manufacturing the display panel 11.

In comparison with FIGS. 11A and 11B, referring to FIGS. 12A and 12B, a structure of the first dam D1 is different, and other aspects are substantially similar.

In one or more embodiments, the first dam D1 may include the first inorganic part D1a, the first-1 metal part D1d, the first-2 metal part D1e, the first-3 metal part D1f, the first-1 organic part D1b, and a first-3 organic part D1g.

In one or more embodiments, the first-3 organic part D1g may be arranged between the first-2 metal part D1e and the first-3 metal part D1f. In one or more embodiments, the first-3 organic part D1g may entirely cover the first inorganic part D1a, the first-1 metal part D1d, and the first-2 metal part D1e. In one or more embodiments, the first-1 organic part D1b may cover the first-3 organic part D1g and the first-3 metal part D1f. In one or more embodiments, the first-3 organic part D1g may include the same material as the fifth insulating layer 110. In one or more embodiments, the first-3 organic part D1g and the fifth insulating layer 110 may be formed in the same process. In one or more embodiments, it may be understood that the first-3 organic part D1g is a part of the fifth insulating layer 110.

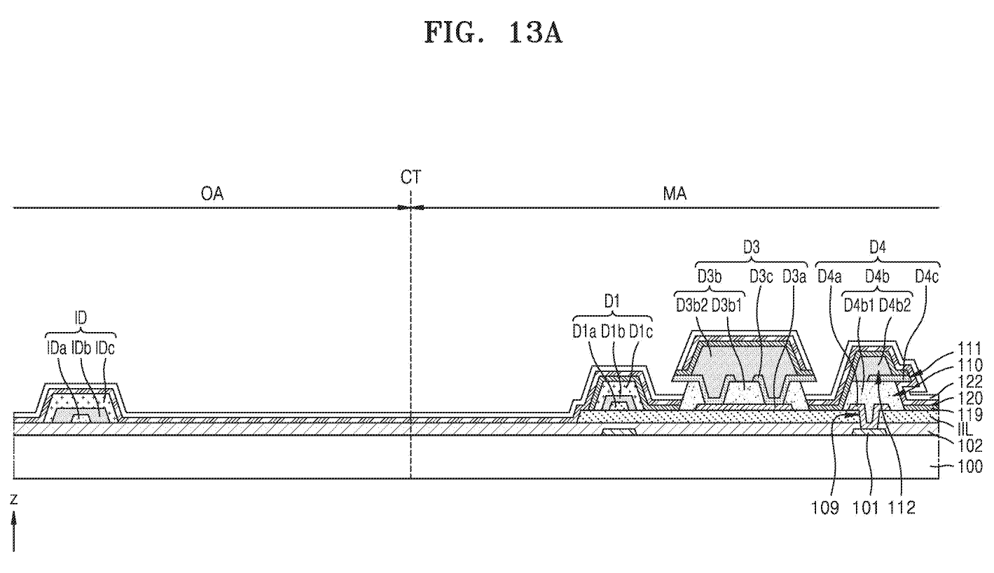

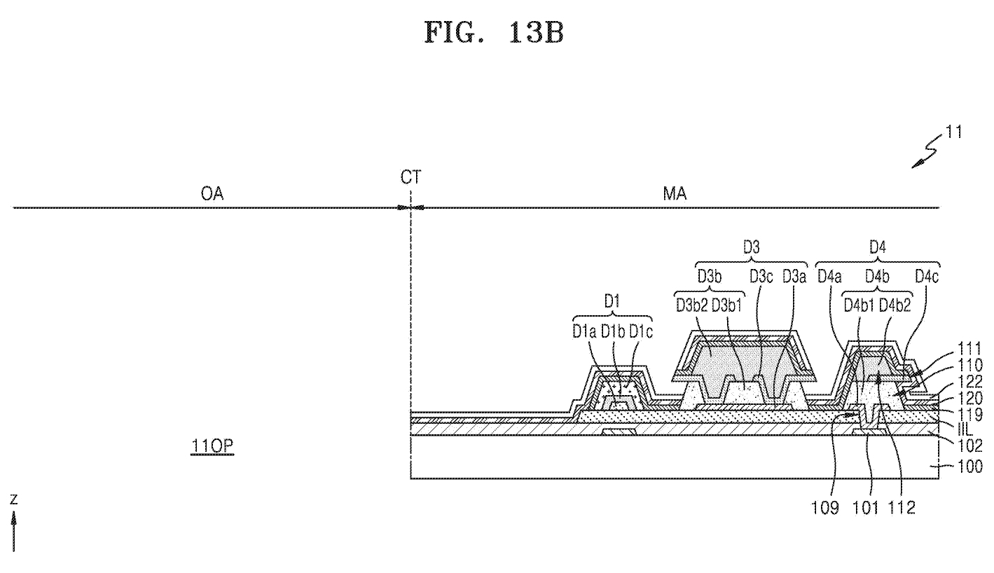

FIGS. 13A and 13B are cross-sectional views of the display panel 11 according to one or more embodiments.

Similar to what is described above with reference to FIGS. 9A and 9B, it may be understood that FIGS. 13A and 13B are cross-sectional views of the display panel 11 and/or cross-sectional views illustrating processes of the method of manufacturing the display panel 11.

In comparison with FIGS. 9A and 9B, referring to FIGS. 13A and 13B, the second dam D2 may be omitted, and the first dam D1 may be arranged on the inorganic insulating layer IIL, and other aspects are substantially similar.

In one or more embodiments, the first inorganic part D1a of the first dam D1 may include the same material as the inorganic insulating layer IIL. In one or more embodiments, the first inorganic part D1a of the first dam D1 and the inorganic insulating layer IIL may be provided as an integrated entity (e.g., as a single element). In another expression, a part of the inorganic insulating layer IIL may protrude, and the protruding part of the inorganic insulating layer IIL may be defined as the first inorganic part D1a of the first dam D1. The first-1 organic part D1b and the first-2 organic part D1c may be arranged on the inorganic insulating layer IIL, e.g., on the first inorganic part D1a.

In one or more embodiments, the first electrode 113 may cover the first dam D1. In one or more embodiments, a part of the first electrode 113 may be arranged between the first dam D1 and the first inorganic encapsulation layer 120.

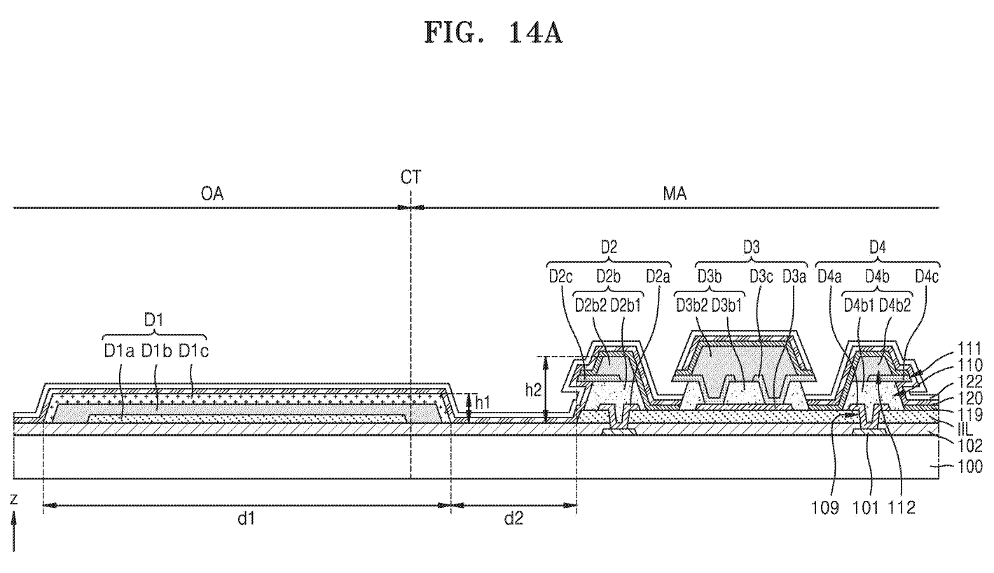

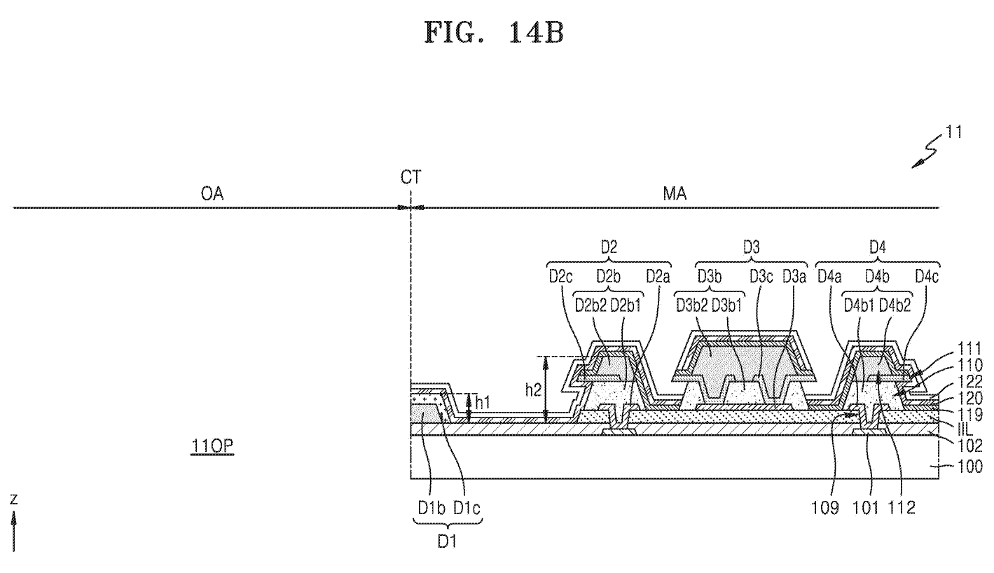

FIGS. 14A and 14B are cross-sectional views of the display panel 11 according to one or more embodiments.

Similar to what is described above with reference to FIGS. 9A and 9B, it may be understood that FIGS. 14A and 14B are cross-sectional views of the display panel 11 and/or cross-sectional views illustrating processes of the method of manufacturing the display panel 11.

In comparison with FIGS. 9A and 9B, referring to FIGS. 14A and 14B, a structure of the first dam D1 is different, and other aspects are substantially similar.

In one or more embodiments, the first dam D1 may extend over both of the opening area OA and the middle area MA. In one or more embodiments, the first dam D1 may include the first inorganic part D1a, the first-1 organic part D1b, and the first-2 organic part D1c. FIG. 14A illustrates one or more embodiments in which the first-1 organic part D1b and the first-2 organic part D1c extend over the opening area OA and the middle area MA. In one or more embodiments, the first inorganic part D1a may also extend over the opening area OA and the middle area MA. A side of the first dam D1 may be exposed by cutting the substrate 100, the first insulating layer 102, the first dam D1, the first inorganic encapsulation layer 120, and the second inorganic encapsulation layer 122, along the cutting line CT. For example, sides of the first-1 organic part D1b and the first-2 organic part D1c may be exposed.

A width of the first dam D1 may be defined as a first distance d1. A distance between an edge of the first dam D1 and an edge of the second dam D2 may be defined as a second distance d2. In one or more embodiments, the second distance d2 may correspond to a distance between an edge of the first-2 organic part D1c and an edge of the second-2 metal part D2c. In one or more embodiments, the first distance d1 may be greater than the second distance d2.

A height of the first dam D1 may be defined as a first height h1. In one or more embodiments, the first height h1 may correspond to a distance from a top surface of the first insulating layer 102 and a top surface of the first-2 organic part D1c. A height of the second dam D2 may correspond to a second height h2. In one or more embodiments, the second height h2 may correspond to a distance from a top surface of the first insulating layer 102 and a top surface of the second-2 organic part D2b2. In one or more embodiments, the first height h1 may be equal to or less than the second height h2.

In the cutting and removing processes, (in an area near the cutting line CT, for example), delamination between the first insulating layer 102 and the first inorganic encapsulation layer 120, or delamination between the first inorganic encapsulation layer 120 and the second inorganic encapsulation layer 122 may occur. The structure of the first dam D1 extending over the middle area MA and the opening area OA, and the first distance d1 being greater than the second distance d2 may decrease a delamination force (force that causes delamination) between the first insulating layer 102 and the first inorganic encapsulation layer 120, and between the first inorganic encapsulation layer 120 and the second inorganic encapsulation layer 122, thereby reducing or preventing (or, at least suppressing) occurrence of the delamination above.

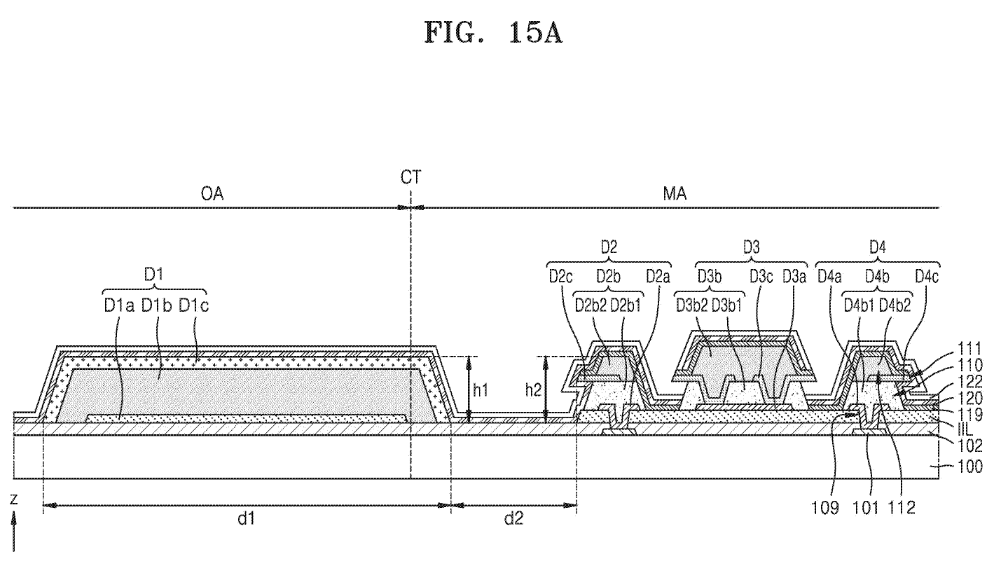

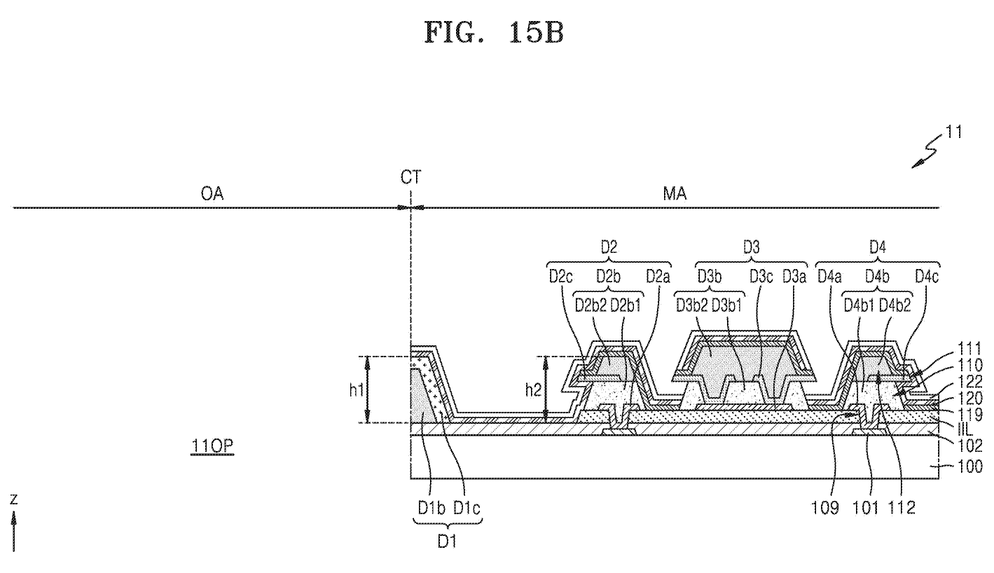

FIGS. 15A and 15B are cross-sectional views of the display panel 11 according to one or more embodiments.

Similar to what is described above with reference to FIGS. 9A and 9B, it may be understood that FIGS. 15A and 15B are cross-sectional views of the display panel 11 and/or cross-sectional views illustrating processes of the method of manufacturing the display panel 11.

In comparison with FIGS. 14A and 14B, referring to FIGS. 15A and 15B, a height of the first dam D1 is different, and other aspects are substantially similar.

In one or more embodiments, a first height h1 of the first dam D1 may be equal to or greater than a second height h2 of the second dam D2. In one or more embodiments, to implement the first height h1, the first-1 organic part D1b may be arranged to have a sufficient thickness. In one or more embodiments, unlike to what is shown in FIG. 15A, to implement the first height h1, the first-1 organic part D1b and/or the first-2 organic part D1c may be arranged to have a sufficient thickness.

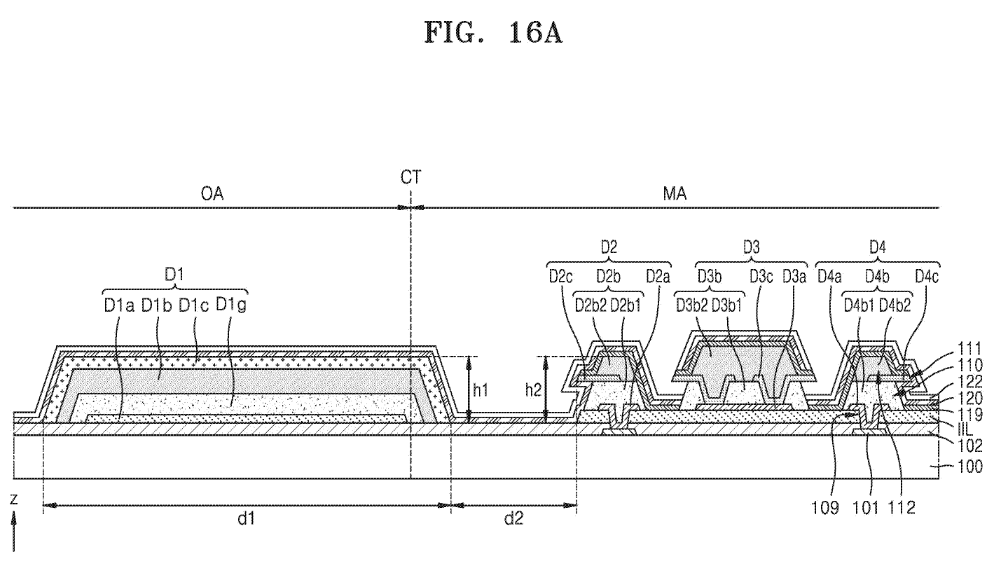

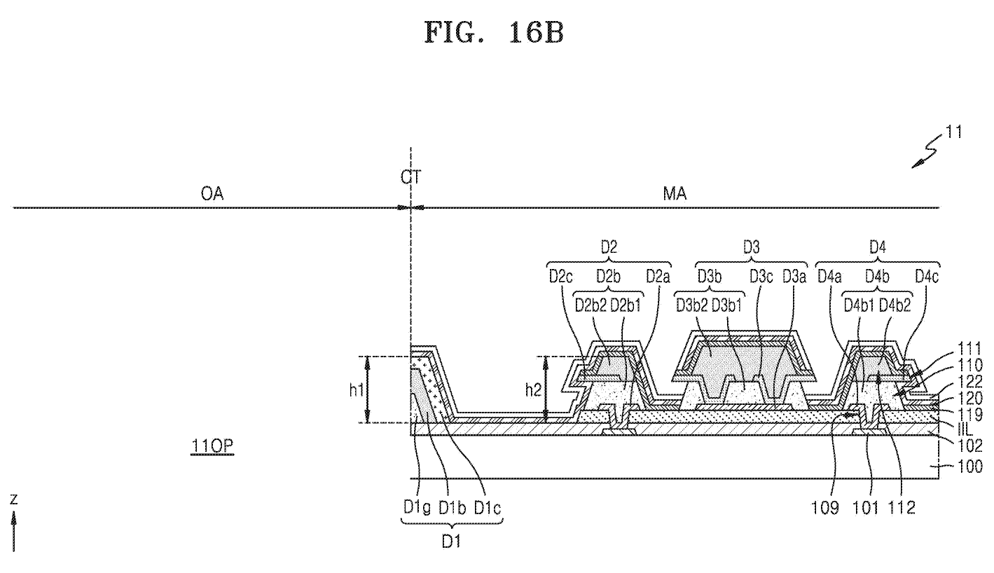

FIGS. 16A and 16B are cross-sectional views of the display panel 11 according to one or more embodiments.

Similar to what is described above with reference to FIGS. 9A and 9B, it may be understood that FIGS. 16A and 16B are cross-sectional views of the display panel 11 and/or cross-sectional views illustrating processes of the method of manufacturing the display panel 11.

In comparison with FIGS. 15A and 15B, referring to FIGS. 16A and 16B, a structure of the first dam D1 is different, and other aspects are substantially similar.

In one or more embodiments, the first height h1 of the first dam D1 may be equal to or greater than the second height h2 of the second dam D2. In one or more embodiments, to implement the first height h1, the first dam D1 may further include the first-3 organic part D1g, in addition to the first inorganic part D1a, the first-1 organic part D1b, and the first-2 organic part D1c.

In one or more embodiments, the first-3 organic part D1g may be arranged between the first inorganic part D1a and the first-1 organic part D1b. In one or more embodiments, the first-3 organic part D1g may entirely cover the first inorganic part D1a. In one or more embodiments, the first-1 organic part D1b may entirely cover the first-3 organic part D1g. In one or more embodiments, the first-3 organic part D1g may include the same material as the fifth insulating layer 110. In one or more embodiments, the first-3 organic part D1g and the fifth insulating layer 110 may be formed in the same process. In one or more embodiments, it may be understood that the first-3 organic part D1g is a part of the fifth insulating layer 110.

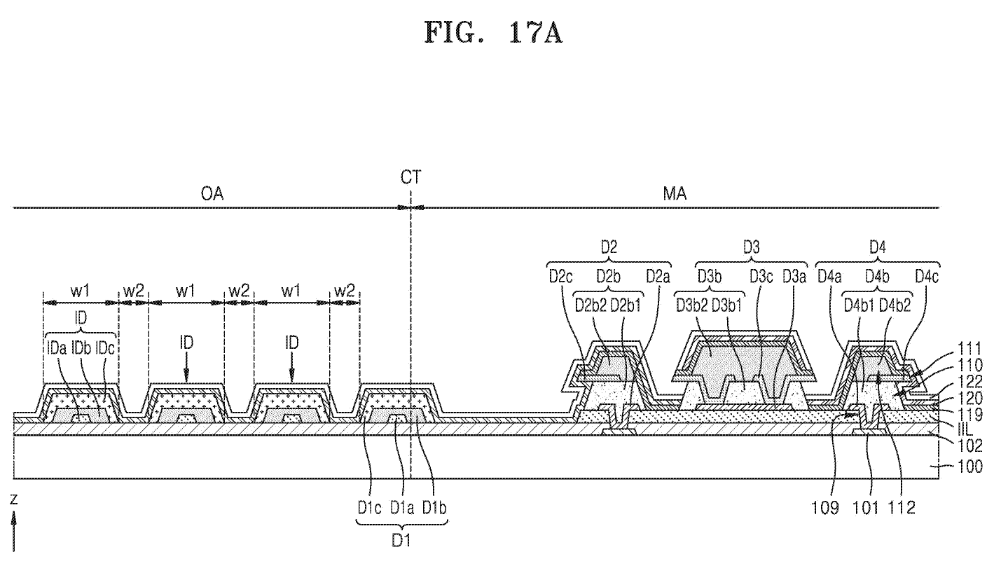

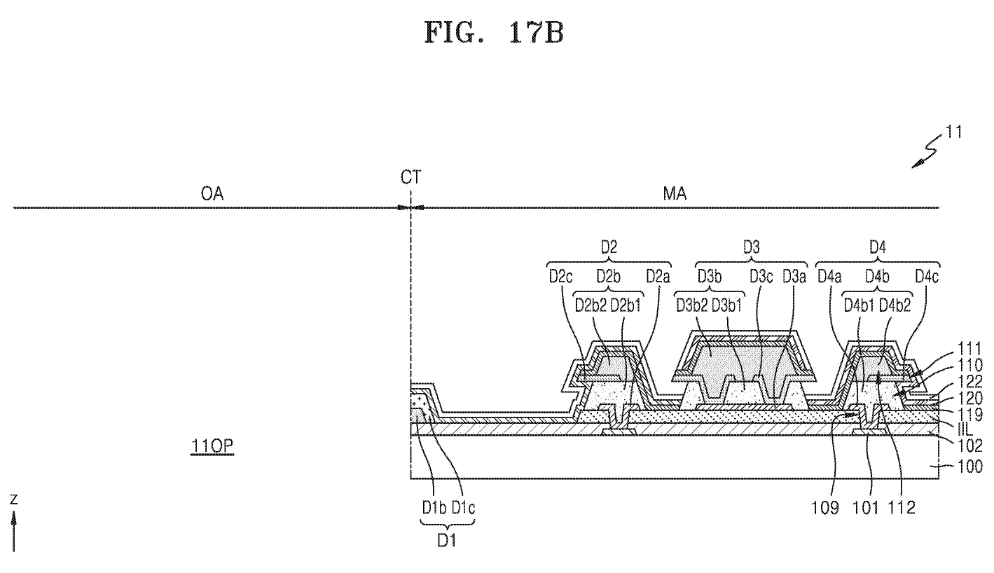

FIGS. 17A and 17B are cross-sectional views of the display panel 11 according to one or more embodiments.

Similar to what is described above with reference to FIGS. 9A and 9B, it may be understood that FIGS. 17A and 17B are cross-sectional views of the display panel 11 and/or cross-sectional views illustrating processes of the method of manufacturing the display panel 11.

Referring to FIGS. 17A and 17B, the first dam D1 may be arranged while extend over the opening area OA and the middle area MA. The inner dam ID may be provided in plural in the opening area OA. The inner dam ID may have the similar stack structure to the first dam D1. In one or more embodiments, the first dam D1 may have the first inorganic part D1a, the first-1 organic part D1b, and the first-2 organic part D1c, and the inner dam ID may include the inner inorganic part IDa, the first inner organic part IDb, and the second inner organic part IDc.

A width of the inner dam ID may be defined as a first width w1. In one or more embodiments, the first width w1 may correspond to a distance between edges of the second inner organic part IDc. A distance between neighboring inner dams ID may be defined as a second width w2. In one or more embodiments, the second width w2 may correspond to a distance between edges of second inner organic parts IDc of the neighboring inner dams ID. In one or more embodiments, the first width w1 may be greater than the second width w2.

The first inorganic encapsulation layer 120 and the second inorganic encapsulation layer 122 may entirely cover the first dam D1 and the inner dams ID.

In the cutting process, the substrate 100, the first insulating layer 102, the first dam D1, the first inorganic encapsulation layer 120, and the second inorganic encapsulation layer 122 may be cut along the cutting line CT. Afterward, a part of the first dam D1, and the inner dams ID, which are arranged in the opening area OA, may be removed.

The true technical scope of the disclosure is defined by the technical spirit of the appended claims.

According to one or more embodiments as described above, an aspect in which delamination between some of a plurality of layers on a substrate is reduced or prevented during a cutting and removing process for forming an opening of a display panel may be provided. The aspect of reducing or preventing the delamination may be achieved by a structure of various dams described above.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, with functional equivalents thereof to be included therein.

What is claimed is:

1. A display panel comprising:
a substrate comprising an opening area, a middle area at least partially surrounding the opening area in plan view, and a display area at least partially surrounding the middle area in plan view;
a light-emitting diode in the display area;
a first dam in the middle area, and comprising two or more selected from a first organic part, a first inorganic part, or a first metal part; and
a second dam between the first dam and the display area, and comprising a second organic part, and a second metal part in the second organic part and having a part protruding beyond a side of the second organic part.

2. The display panel of claim 1, wherein the first dam comprises the first inorganic part above the substrate, a first-1 organic part covering the first inorganic part, and a first-2 organic part covering the first-1 organic part.

3. The display panel of claim 1, wherein the first dam comprises the first inorganic part above the substrate, a first-1 metal part in the first inorganic part, a first-2 metal part above the first inorganic part, and a first-3 metal part above the first-2 metal part.

4. The display panel of claim 3, further comprising an encapsulation layer covering the first dam and the second dam, and directly contacting the first-2 metal part and the first-3 metal part of the first dam.

5. The display panel of claim 3, wherein the first dam further comprises a first-1 organic part covering the first inorganic part, the first-1 metal part, the first-2 metal part, and the first-3 metal part.

6. The display panel of claim 5, wherein the first dam further comprises a first-3 organic part between the first-2 metal part and the first-3 metal part, and covering the first inorganic part, the first-1 metal part, the first-2 metal part.

7. The display panel of claim 3, wherein the first-3 metal part of the first dam is at a same layer as the second metal part of the second dam.

8. The display panel of claim 1, wherein the substrate defines an opening corresponding to the opening area.

9. The display panel of claim 1, wherein the light-emitting diode comprises a first electrode above the substrate, an emission layer above the first electrode, and a second electrode above the emission layer and disconnected at an edge of the second metal part that extends toward the middle area and protrudes over the side of the second organic part of the second dam.

10. A method of manufacturing a display panel, the method comprising:
forming a light-emitting diode in a display area of a substrate comprising an opening area, a middle area at least partially surrounding the opening area in plan view, and the display area at least partially surrounding the middle area in plan view;
forming a first dam extending over the opening area and the middle area;
forming, between the first dam and the display area, a second dam comprising a second organic part, and a second metal part in the second organic part, and having a part protruding over a side of the second organic part; and
cutting the first dam and the substrate along a boundary between the opening area and the middle area.

11. The method of claim 10, wherein the first dam comprises a first inorganic part above the substrate, a first-1 organic part above the first inorganic part, and a first-2 organic part above the first-1 organic part.

12. The method of claim 11, wherein a width of the first dam is greater than a distance between the first dam and the second dam.

13. The method of claim 12, wherein a height of the first dam is equal to or greater than a height of the second dam.

14. The method of claim 13, wherein the first dam further comprises a first-3 organic part between the first inorganic part and the first-1 organic part.

15. The method of claim 10, further comprising arranging, in the opening area, an inner dam having a same stack structure as the first dam.

16. The method of claim 15, further comprising arranging two neighboring inner dams having a distance therebetween that is less than a width of the inner dams.

17. The method of claim 10, further comprising arranging an encapsulation layer covering the first dam and the second dam,
wherein the encapsulation layer is also cut in the cutting of the first dam and the substrate.

18. The method of claim 10, further comprising removing a part of the substrate and a part of the first dam corresponding to the opening area.

19. An electronic device comprising a display panel, wherein the display panel comprises:
a substrate comprising an opening area, a middle area at least partially surrounding the opening area in plan view, and a display area at least partially surrounding the middle area in plan view;
a light-emitting diode in the display area;
a first dam in the middle area, and comprising two or more selected from a first organic part, a first inorganic part, or a first metal part; and
a second dam between the first dam and the display area, and comprising a second organic part, and a second metal part in the second organic part, and having a part protruding over a side of the second organic part.

20. A method of manufacturing an electronic device, the method comprising:
manufacturing the display panel using the method of claim 10; and
coupling the display panel with a housing.
